(19) United States
(12) Patent Application Publication
(10) Pub. No.: US 2023/0260741 A1
(43) Pub. Date: Aug. 17, 2023

(54) ION IMPLANTER AND ION IMPLANTATION METHOD

(71) Applicant: SUMITOMO HEAVY INDUSTRIES ION TECHNOLOGY CO., LTD., Tokyo (JP)

(72) Inventors: Tetsuya Kudo, Ehime (JP); Akihiro Ochi, Ehime (JP); Shinji Ebisu, Ehime (JP)

(21) Appl. No.: 18/108,429

(22) Filed: Feb. 10, 2023

(30) Foreign Application Priority Data
Feb. 15, 2022 (JP) 2022-021335

(51) Int. Cl. H01J 37/20; H01J 37/317; H01J 37/147; H01J 37/04

(52) U.S. Cl. CPC H01J 37/20; H01J 37/3171; H01J 37/1475; H01J 37/045; H01J 2237/20214; H01J 2237/20228; H01J 2237/24564; H01J 2237/2007; H01J 37/09

(57) ABSTRACT

The ion implantation method includes (a) moving a wafer adjusted to have a first implantation angle with respect to an ion beam from a beam irradiation range toward a beam non-irradiation range; (b) starting a change of the wafer from the first implantation angle to a second implantation angle while the wafer is moved within the beam non-irradiation range after the wafer having the first implantation angle is moved from the beam irradiation range; (c-1) reversing a movement direction of the wafer at an end of the beam non-irradiation range and moving the wafer toward the beam irradiation range; and (c-2) completing the change of the wafer from the first implantation angle to the second implantation angle while the wafer is moved within the beam non-irradiation range before the wafer is returned to the beam irradiation range.

### RELATED APPLICATIONS

The content of Japanese Patent Application No. 2022-021335, on the basis of which priority benefits are claimed in an accompanying application data sheet, is in its entirety incorporated herein by reference.

### BACKGROUND

### Technical Field

Certain embodiments of the present invention relate to an ion implanter and an ion implantation method.

### Description of Related Art

The related art discloses an ion implanter that irradiates the same reciprocating wafer with ion beams having different implantation angles a plurality of times. In a case where the irradiating direction of the ion beam is substantially constant, the implantation angle of the ion beam with respect to the wafer is determined, for example, by a set of a twist angle (rotation angle) and a tilt angle of the wafer. An end portion of a reciprocation range of the wafer is a beam non-irradiation range in which the wafer is not irradiated with the ion beam. Therefore, when the movement direction of the wafer is reversed at the end of the reciprocation range which is also the end of the beam non-irradiation range, the twist angle and/or the tilt angle of the wafer is changed. Accordingly, the implantation angle can be changed without exposing the wafer to the ion beam.

### SUMMARY

According to an embodiment of the present invention, there is provided an ion implanter including a support mechanism that supports a workpiece to be irradiated with an ion beam; an implantation angle adjustment mechanism capable of adjusting an implantation angle of the workpiece supported with the support mechanism with respect to the ion beam; a drive mechanism that reciprocates the support mechanism in a direction intersecting with the ion beam, a reciprocation range of the drive mechanism includes a beam irradiation range in which at least a part of the workpiece is irradiated with the ion beam, and a beam non-irradiation range which is adjacent to at least one end of the beam irradiation range and in which the workpiece is not irradiated with the ion beam; a processor that controls the implantation angle adjustment mechanism and the drive mechanism; and a memory in which a program is stored. On the basis of the program, the processor executes (a) moving the workpiece, which has been adjusted so as to have a first implantation angle by the implantation angle adjustment mechanism, from the beam irradiation range toward the beam non-irradiation range with the drive mechanism; (b) starting a change of the workpiece from the first implantation angle to a second implantation angle different from the first implantation angle with the implantation angle adjustment mechanism while the workpiece is moved within the beam non-irradiation range after the workpiece having the first implantation angle is moved from the beam irradiation range to the beam non-irradiation range with the drive mechanism, subsequently to the step (a); (c-1) reversing a movement direction of the workpiece at an end of the beam non-irradiation range with the drive mechanism and moving the workpiece toward the beam irradiation range, subsequently to the step (b); and (c-2) completing the change of the workpiece from the first implantation angle to the second implantation angle with the implantation angle adjustment mechanism while the workpiece is moved within the beam non-irradiation range with the drive mechanism before the workpiece is returned from the beam non-irradiation range to the beam irradiation range with the drive mechanism, subsequently to the step (b).

According to another embodiment of the present invention, there is provided an ion implantation method. The method includes (a) moving a workpiece adjusted to have a first implantation angle with respect to an ion beam from a beam irradiation range in which at least a part of the workpiece is irradiated with the ion beam toward a beam non-irradiation range which is adjacent to at least one end of the beam irradiation range and in which the workpiece is not irradiated with the ion beam; (b) starting a change of the workpiece from the first implantation angle to a second implantation angle different from the first implantation angle while the workpiece is moved within the beam non-irradiation range after the workpiece having the first implantation angle is moved from the beam irradiation range to the beam non-irradiation range, subsequently to the step (a); (c-1) reversing a movement direction of the workpiece at an end of the beam non-irradiation range and moving the workpiece toward the beam irradiation range, subsequently to the step (b); and (c-2) completing the change of the workpiece from the first implantation angle to the second implantation angle while the workpiece is moved within the beam non-irradiation range before the workpiece is returned from the beam non-irradiation range to the beam irradiation range, subsequently to the step (b).

### BRIEF DESCRIPTION OF THE DRAWINGS

FIG. 1 is a top view showing a schematic configuration of an ion implanter.

FIG. 2 is a side view showing the schematic configuration of the ion implanter.

FIG. 3 schematically shows an ion beam deflected from an irradiation-enabled direction to an irradiation-disabled direction by an electric field.

FIG. 4 schematically shows an ion beam deflected from the irradiation-enabled direction to the irradiation-disabled direction by a magnetic field.

FIGS. 5A and 5B show a modification example of a beam blocking mechanism.

FIGS. 6A and 6B show a modification example of the beam blocking mechanism.

FIGS. 7A and 7B show a modification example of the beam blocking mechanism.

FIGS. 8A and 8B show a modification example of the beam blocking mechanism.

FIGS. 9A and 9B show a modification example of the beam blocking mechanism.

FIG. 10 is a front view showing a schematic configuration of an implantation processing chamber.

FIG. 11 is a top view schematically showing an implantation processing chamber in an implantation process.

FIG. 12 is a top view schematically showing the implantation processing chamber in a preparation process.

FIG. 13 is a top view schematically showing the implantation processing chamber in a calibration process.

FIG. 14 is a diagram schematically showing the implantation process with a non-zero tilt angle.

FIGS. 15A to 15D schematically shows changes in a twist angle by a twist angle adjustment mechanism.

FIGS. 16A to 16D schematically show a non-zero tilt angle implantation process in which the twist angles are different from each other.

FIG. 17 is a functional block diagram of the ion implanter.

FIG. 18 is a timing chart schematically showing a basic operation in an implantation process of the ion implanter.

FIG. 19 schematically shows an example in which a beam scanning function and a beam deflection function are realized with one beam scanning device.

### DETAILED DESCRIPTION

In the ion implanter of the related art, it is necessary to change the twist angle and/or the tilt angle of the wafer during the movement direction reversal at the end of the reciprocation range (beam non-irradiation range) of the wafer. Therefore, the time for which the wafer stays in the beam non-irradiation range becomes long. Since the wafer within the beam non-irradiation range is not irradiated with the ion beam, there is a risk that the efficiency of the ion implantation processing degrades as a result.

It is desirable to provide an ion implanter or the like capable of shortening the stay time of a workpiece in a beam non-irradiation range when an implantation angle of the workpiece with respect to an ion beam is changed.

In this aspect, the implantation angle of the workpiece starts to change from the first implantation angle to the second implantation angle after the workpiece at the first implantation angle moves from the beam irradiation range to the beam non-irradiation range and before the workpiece at the first implantation angle arrives at a movement direction reversing end (hereinafter abbreviated as a reversing end) of the beam non-irradiation range, and completes to change from the first implantation angle to the second implantation angle while the workpiece moves within the beam non-irradiation range before returning from the beam non-irradiation range to the beam irradiation range. In this way, by performing the movement of the workpiece within the beam non-irradiation range and the change of the implantation angle in parallel, the stay time of the workpiece in the beam non-irradiation range can be shortened. As a result, since the stay time in the beam irradiation range, for which the workpiece is irradiated with the ion beam, is relatively long, the efficiency of the ion implantation processing can be improved.

In addition, optional combinations of the above components and those obtained by exchanging the expressions of the present invention with each other between methods, devices, systems, recording media, computer programs, and the like are also effective as aspects of the present invention.

Hereinafter, embodiments for carrying out the present invention will be described in detail with reference to the drawings. In the descriptions or drawings, the same or equivalent components, members, and processing are designated by the same reference numerals, and redundant descriptions will be omitted. The scales and shapes of the respective parts shown in the drawings are set for convenience in order to facilitate the descriptions, and should not be interpreted as limiting unless otherwise specified. The embodiments are merely examples and do not limit the scope of the present invention. All the features and combinations to be described in the embodiments are not necessarily essential to the invention.

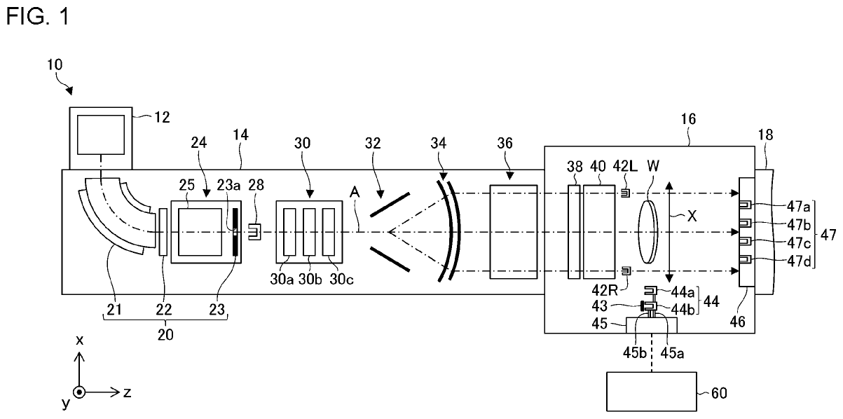

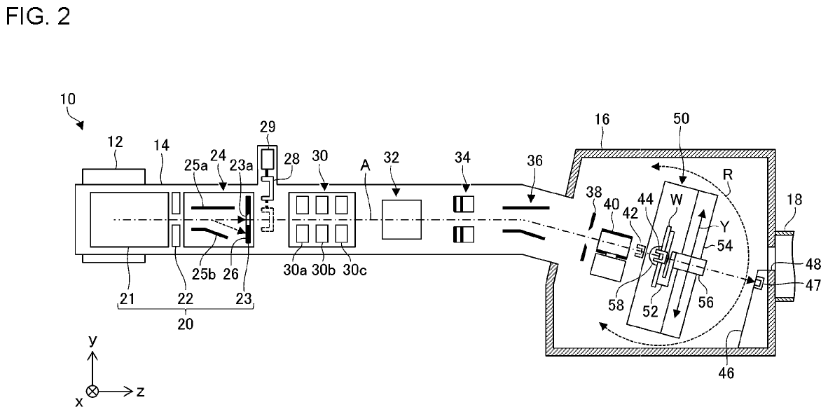

FIG. 1 is a top view showing a schematic configuration of an ion implanter 10 according to an embodiment of the present invention, and FIG. 2 is a side view showing the schematic configuration of the ion implanter 10. The ion implanter 10 is a device that performs ion implantation processing on a front surface of a workpiece W. The workpiece W is, for example, a substrate such as a semiconductor wafer or a display device. In the present specification, the workpiece W is also referred to as a wafer W for convenience, but it is not intended to limit an ion implantation processing target to a specific object or substance such as a semiconductor wafer.

The ion implanter 10 can irradiate the entire processing surface of the wafer W with an ion beam by causing an ion beam to perform reciprocating scanning in one direction (hereinafter, also referred to as a scanning direction, a beam scanning direction, or a beam movement direction) and reciprocating the wafer W in a direction (hereinafter, also referred to as a reciprocating motion direction, a reciprocating movement direction, or a wafer movement direction) perpendicular to the scanning direction. In the present specification, a traveling direction (hereinafter, also referred to as a beam traveling direction) of an ion beam which travels along a designed beamline A is defined as a z direction, and a plane perpendicular to the z direction is defined as an xy plane. In a case where the workpiece W is scanned with the ion beam, the scanning direction (beam movement direction) of the ion beam is defined as an x direction, and a y direction perpendicular to the z direction and the x direction is defined as the wafer movement direction. In this way, the reciprocating scanning with the ion beam is performed in the x direction, and the reciprocating motion of the wafer W is performed in the y direction.

The ion implanter 10 includes an ion generation device 12, a beamline unit 14, an implantation processing chamber 16, and a wafer transfer device 18. The ion generation device 12 supplies an ion beam to the beamline unit 14. The beamline unit 14 transports the ion beam supplied from the ion generation device 12 to the implantation processing chamber 16. The wafer W serving as an ion implantation target is accommodated in the implantation processing chamber 16, and ion implantation processing is performed in which the wafer W is irradiated with an ion beam supplied from the beamline unit 14. The wafer transfer device 18 serving as a transfer device transfers an unprocessed wafer before the ion implantation processing into the implantation processing chamber 16 and transfers a processed wafer after the ion implantation processing from the implantation processing chamber 16. In addition, although not shown, the ion implanter 10 is provided with an evacuating system for providing desired vacuum environments to the ion generation device 12, the beamline unit 14, the implantation processing chamber 16, and the wafer transfer device 18.

The beamline unit 14 includes a mass analyzing unit 20, a beam park device 24, a beam shaping unit 30, a beam scanning device 32, a beam parallelizing unit 34, and an angular energy filter (AEF) 36 in order from an upstream side of the beamline A. In addition, the upstream (side) of the beamline A is a side closer to the ion generation device 12, and the downstream (side) of the beamline A is a side closer to the implantation processing chamber 16 (or a beam stopper 46).

The mass analyzing unit 20 provided downstream of the ion generation device 12 selects or extracts desired ion species to be used for the ion implantation processing from the ion beam generated by the ion generation device 12 through mass analysis. The mass analyzing unit 20 includes a mass analyzing magnet 21, a mass analyzing lens 22, and a mass analyzing slit 23.

The mass analyzing magnet 21 applies a magnetic field to the ion beam extracted from the ion generation device 12 and deflects the ion beam to travel in different trajectories depending on the value of a mass-to-charge ratio M=m/q (m is mass and q is a charge) of ions. The mass analyzing magnet 21, for example, applies a magnetic field in the −y direction to the ion beam to deflect the ion beam in the x direction. The magnetic field intensity of the mass analyzing magnet 21 is adjusted such that ion species having a desired mass-to-charge ratio M can pass through the downstream mass analyzing slit 23.

The mass analyzing lens 22 is provided downstream of the mass analyzing magnet 21 (and upstream of the mass analyzing slit 23), and adjusts a focusing power/defocusing power (or the degree of convergence/degree of defocusing of the ion beam) with respect to the ion beam. The mass analyzing lens 22 adjusts the focusing position of the ion beam passing through the mass analyzing slit 23 in a beam traveling direction (z direction) and adjusts the mass resolution M/dM of the mass analyzing unit 20. In addition, the mass analyzing lens 22 may not be provided in the mass analyzing unit 20.

The mass analyzing slit 23 is provided at a downstream position away from the mass analyzing lens 22. The mass analyzing slit 23 has a rectangular opening 23a having a relatively short width in the x direction and a relatively long height in the y direction. Since the width direction (x direction) of the opening 23a coincides with a beam deflection direction (x direction) by the mass analyzing magnet 21, the width (dimension in the x direction) of the opening 23a mainly contributes to the selection of desired ion species according to the mass-to-charge ratio M in the mass analyzing slit 23.

The mass analyzing slit 23 may make the slit width (the width of the opening 23a) variable in order to adjust the mass resolution. For example, the slit width may be adjusted by configuring the mass analyzing slit 23 with two shield members that are relatively movable in the slit width direction (x direction) and changing the distance between the two shield members in the slit width direction. Additionally, the mass analyzing slit 23 may change the slit width by switching between a plurality of slits having different slit widths.

The beam park device 24 constitutes a beam deflection device that deflects the ion beam by at least one of an electric field and a magnetic field. Specifically, the beam park device 24 is switchable between an irradiation-enabled state in which the ion beam is directed in an irradiation-enabled direction in which the wafer W can be irradiated with the ion beam and an irradiation-disabled state in which the ion beam is directed in an irradiation-disabled direction in which the wafer W cannot be irradiated with the ion beam. In the example of FIG. 2, an arrow directed to the inside of the opening 23a of the mass analyzing slit 23 represents the irradiation-enabled direction, and an arrow directed to the beam dump 26 outside the opening 23a of the mass analyzing slit 23 represents the irradiation-disabled direction. Here, the mass analyzing slit 23 is a slit through which at least a part of the ion beam directed in the irradiation-enabled direction passes, and is provided between the beam park device 24 serving as the beam deflection device and a wafer holding device 52 (FIG. 2) serving as a holding device to be described below.

The beam park device 24 in the irradiation-disabled state temporarily retracts the ion beam from the beamline A and shields the ion beam directed to the downstream implantation processing chamber 16 (or wafer W) with the beam dump 26. That is, the ion beam directed in the irradiation-disabled direction collides with the beam dump 26 outside the opening 23a of the mass analyzing slit 23 and is blocked. The beam park device 24 can be disposed at an optional position on the beamline A but is disposed between the mass analyzing lens 22 and the mass analyzing slit 23 in the shown example. As mentioned above, since a certain distance or more is required between the mass analyzing lens 22 and the mass analyzing slit 23, the space can be efficiently used by disposing the beam park device 24 between the mass analyzing lens 22 and the mass analyzing slit 23. As a result, the beamline A can be shortened, and the entire ion implanter 10 can be downsized as compared to a case where the beam park device 24 is disposed at another location.

The beam park device 24 shown in FIGS. 1 and 2 constitutes a type of beam deflection device that deflects the ion beam by an electric field. The beam park device 24 includes a pair of park electrodes 25 (25a, 25b) and the beam dump 26. The pair of park electrodes 25a and 25b faces each other in the y direction with the beamline A interposed therebetween. The beam park device 24 switches the traveling direction of the ion beam between the irradiation-enabled direction and the irradiation-disabled direction depending on a change in the electric field in the y direction caused by a change in the voltage to be applied to the pair of park electrodes 25a and 25b.

In the example of FIG. 2, when no voltage is applied to the pair of park electrodes 25a and 25b (that is, when the voltage is substantially zero), the irradiation-enabled state is brought about in which a beam of the desired ion species to be used for the ion implantation processing goes straight in the irradiation-enabled direction and passes through the inside of the opening 23a of the mass analyzing slit 23, without being deflected. On the other hand, when a voltage is applied to the pair of park electrodes 25a and 25b (that is, when the voltage has a significant non-zero value), the irradiation-disabled state is brought about in which the beam of the desired ion species to be used for the ion implantation processing is deflected in the −y direction, travels in the irradiation-disabled direction, collides with the beam dump 26 outside the opening 23a of the mass analyzing slit 23, and is shielded.

In the above example, during the non-deflection of the ion beam in which no voltage is applied to the pair of park electrodes 25a and 25b, the ion beam travels in the irradiation-enabled direction, and during the deflection of the ion beam in which a voltage is applied to the pair of park electrodes 25a and 25b, the ion beam travels in the irradiation-disabled direction. However, the ion beam during the non-deflection may travel in the irradiation-disabled direction, and the ion beam during the deflection may travel in the irradiation-enabled direction. In this case, for example, the beam dump 26 may be provided at the position of the opening 23a of the mass analyzing slit 23 in FIG. 2, and the opening 23a of the mass analyzing slit 23 may be provided at the position of the beam dump 26 in FIG. 2. In this case, a configuration downstream of the opening 23a is also provided on the beamline A of the ion beam (deflected)passing through the opening 23a.

Additionally, the ion beam traveling in the irradiation-enabled direction and the ion beam traveling in the irradiation-disabled direction may be deflected by different voltages applied to the pair of park electrodes 25a and 25b. For example, in a case where the irradiation-enabled direction (the direction in which the opening 23a of the mass analyzing slit 23 is located) forms a first deflection angle Θ1 with respect to an incident direction of the ion beam into the beam park device 24, and the irradiation-disabled direction (the direction in which the beam dump 26 is located) forms a second deflection angle Θ2 that is significantly different from the first deflection angle Θ1 with respect to the incident direction of the ion beam into the beam park device 24, the direction in which the beam of the desired ion species travels is switched between the irradiation-enabled direction and the irradiation-disabled direction by switching the voltage to be applied to the pair of park electrodes 25a and 25b between a first voltage V1 that realizes the first deflection angle Θ1 and a second voltage V2 (≠V1) that realizes the second deflection angle Θ2.

As described above, the facing direction of the pair of park electrodes 25a and 25b is the y direction and is perpendicular to the beam deflection direction (x direction) of the mass analyzing magnet 21. For this reason, the deflection voltage in the y direction to be applied between the pair of park electrodes 25a and 25b does not hinder the selection of the desired ion species according to the mass-to-charge ratio M performed in the x direction by the mass analyzing magnet 21.

In the example of FIG. 2, the first park electrode 25a is disposed above the beamline A in the direction of gravity (the facing direction of the first park electrode 25a and the second park electrode 25b), and the second park electrode 25b is disposed below the beamline A in the direction of gravity. The beam dump 26 provided downstream of the first park electrode 25a and the second park electrode 25b is disposed below the beamline A in the direction of gravity and below the opening 23a of the mass analyzing slit 23 in the direction of gravity. The beam dump 26 is, for example, a wall-like portion of the mass analyzing slit 23 in which the opening 23a is not formed. In addition, the beam dump 26 may be configured separately from the mass analyzing slit 23.

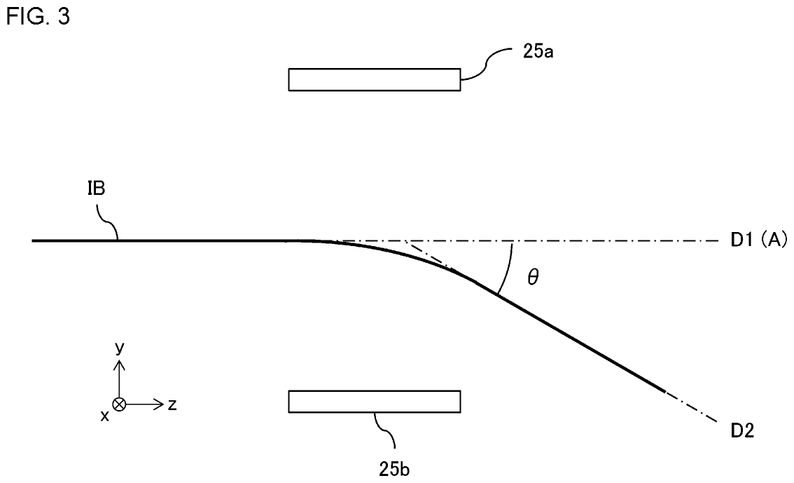

FIG. 3 schematically shows an ion beam IB that is deflected from an irradiation-enabled direction D1 (or the beamline A) to an irradiation-disabled direction D2 by a voltage applied to the pair of park electrodes 25a and 25b. A deflection angle θ of the shown ion beam IB is an angle formed between the irradiation-enabled direction D1 and the irradiation-disabled direction D2. Here, the ion beam IB travels while being bent in a region between the electrodes and in the vicinity thereof in which an electric field between the pair of park electrodes 25a and 25b acts. The deflection angle θ of the ion beam TB is defined as an angle formed by a straight line in the irradiation-enabled direction D1 that goes straight before the ion beam IB is bent, and a straight line in the irradiation-disabled direction D2 that goes straight after the ion beam IB is bent. When the deflection angle θ is too small, there is a risk that a part of the ion beam IB may enter the opening 23a of the mass analyzing slit 23 even in the deflection, and when the deflection angle θ is too large, the mass analyzing slit 23 constituting the beam dump 26 is increased in size. As a result of the study by the present inventor, it is preferable that the deflection angle θ formed by the irradiation-enabled direction D1 and the irradiation-disabled direction D2 is from 2 degrees to 60 degrees. Additionally, the deflection angle θ is more preferably from 3 degrees to 45 degrees, and even more preferably from 5 degrees to 30 degrees.

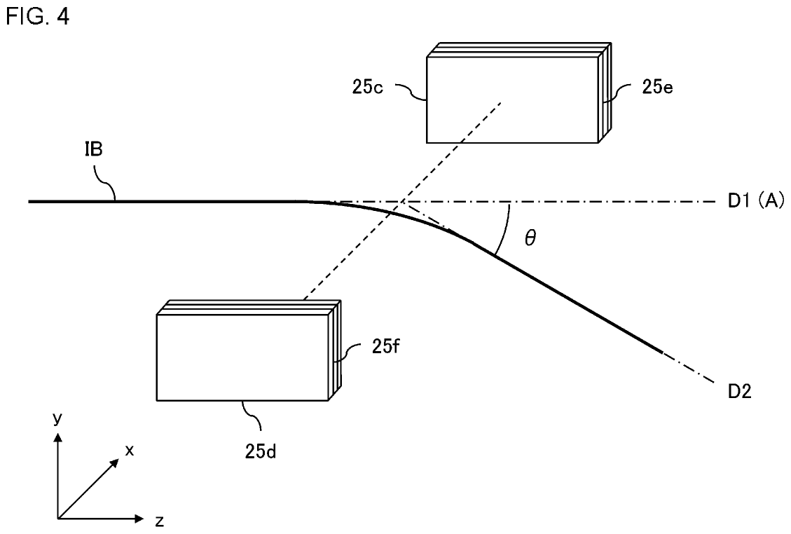

FIG. 4 schematically shows the ion beam IB that is deflected from the irradiation-enabled direction D1 (or the beamline A) to the irradiation-disabled direction D2 by a magnetic field applied between the pair of magnetic poles 25c and 25d. While the beam park device 24 shown in FIGS. 1 to 3 constitutes a type of beam deflection device that deflects the ion beam by an electric field, the beam park device 24 according to a modification example of FIG. 4 constitutes a type of beam deflection device that deflects the ion beam by a magnetic field.

The beam park device 24 includes the pair of magnetic poles 25c and 25d that faces each other in the x direction with the ion beam IB interposed therebetween. Each of the magnetic poles 25c and 25d is a core of a magnetic material such as iron, and coils 25e and 25f are wound around the outer peripheries of the cores. The magnetic poles 25c and 25d and the coils 25e and 25f constitute an electromagnet that causes a magnetic field change in the x direction by changing an electric current to be applied to the coils 25e and 25f. Since the ion beam IB traveling in the z direction receives a Lorentz force in the −y direction due to the magnetic field in the x direction between the magnetic poles 25c and 25d, the traveling direction of the ion beam IB is switchable between the irradiation-enabled direction D1 and the irradiation-disabled direction D2 similarly to FIG. 3. In addition, instead of or in addition to the coils 25e and 25f wound around the magnetic poles 25c and 25d, a coil may be wound around a yoke (not shown) that magnetically connects the pair of magnetic poles 25c and 25d to each other.

In the example of FIG. 4, when a magnetic field in the x direction is not applied between the pair of magnetic poles 25c and 25d, the irradiation-enabled state is brought about in which a beam of the desired ion species to be used for the ion implantation processing goes straight in the irradiation-enabled direction and passes through the inside of the opening 23a of the mass analyzing slit 23, without being deflected. On the other hand, when a magnetic field in the x direction is applied between the pair of magnetic poles 25c and 25d, the irradiation-disabled state is brought about in which the beam of the desired ion species to be used for the ion implantation processing is deflected in the −y direction, travels in the irradiation-disabled direction, collides with the beam dump 26 outside the opening 23a of the mass analyzing slit 23, and is shielded.

In the above example, during the non-deflection of the ion beam in which no magnetic field is applied between the pair of magnetic poles 25c and 25d, the ion beam travels in the irradiation-enabled direction, and during the deflection of the ion beam in which a magnetic field is applied between the pair of magnetic pole 25c and 25d, the ion beam travels in the irradiation-disabled direction. However, the ion beam during the non-deflection may travel in the irradiation-disabled direction, and the ion beam during the deflection may travel in the irradiation-enabled direction. Additionally, the ion beam traveling in the irradiation-enabled direction and the ion beam traveling in the irradiation-disabled direction may be deflected by different magnetic fields applied between the pair of magnetic poles 25c and 25d.

In addition, instead of or in addition to the beam park device 24 according to the embodiment of FIGS. 1 to 3 or the modification example of FIG. 4, the mass analyzing magnet 21 in the mass analyzing unit 20 may be used as a beam deflection device that deflects the ion beam between the irradiation-enabled direction and the irradiation-disabled direction by a magnetic field. As mentioned above, the mass analyzing magnet 21 applies a magnetic field in the −y direction to deflect the ion beam in the x direction, and the ion species having the desired mass-to-charge ratio M pass through the opening 23a of the mass analyzing slit 23 in the irradiation-enabled state. On the other hand, in the irradiation-disabled state, the magnetic field in the y direction of the mass analyzing magnet 21 is changed to deflect an ion beam containing desired ion species to a position in the x direction deviating from the opening 23a of the mass analyzing slit 23. In this case, the beam dump 26 provided at a position deviated from the opening 23a in the y direction in the example of FIG. 2 is provided at a position deviating from the opening 23a in the x direction. Additionally, the ion beam may be deflected between the irradiation-enabled direction and the irradiation-disabled direction by combining the electric field deflection type beam park device 24 as in the embodiment of FIGS. 1 to 3 and the magnetic field deflection type beam park device 24 as in the modification example of FIG. 4.

Hereinafter, the various beam park devices 24 as mentioned above, the mass analyzing magnet 21 in the mass analyzing unit 20 functioning as the beam deflection device, and the like will be collectively referred to as the beam deflection device 24.

In FIGS. 1 and 2, an injector Faraday cup 28 that also functions as a beam blocking mechanism is provided downstream of the mass analyzing slit 23. The injector Faraday cup 28 is capable of being moved into and out of the beamline A by the operation of an injector drive unit 29. The injector drive unit 29 moves the injector Faraday cup 28 in the direction (for example, the y direction) perpendicular to an extending direction (z direction) of the beamline A. As shown by a broken line in FIG. 2, in a case where the injector Faraday cup 28 is disposed on the beamline A, a blocking state is brought about in which the ion beam directed to the downstream side is physically blocked. On the other hand, as shown by a solid line in FIG. 2, in a case where the injector Faraday cup 28 is removed from the beamline A, a non-blocking state is brought about in which the ion beam directed to the downstream side passes through without being physically blocked. In this way, the injector Faraday cup 28 and the injector drive unit 29 function as a beam blocking mechanism that is switchable between a blocking state in which the ion beam is physically blocked and a non-blocking state in which the ion beam is allowed to pass therethrough.

The injector Faraday cup 28 measures the beam current of the ion beam mass-analyzed by the mass analyzing unit 20. By measuring the beam current while changing the magnetic field intensity of the mass analyzing magnet 21, the injector Faraday cup 28 can acquire the mass analysis spectrum of the ion beam. This mass analysis spectrum is used, for example, to calculate the mass resolution of the mass analyzing unit 20.

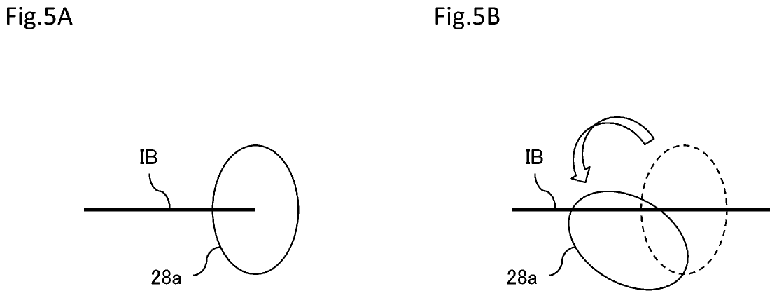

FIG. 5A to FIG. 9B show modification examples of the beam blocking mechanisms. A in each drawing (FIG. 5A or the like) shows a blocking state in which the beam blocking mechanism physically blocks the ion beam IB, and B (FIG. 5B or the like) in each drawing shows a non-blocking state in which the beam blocking mechanism allows the ion beam IB to pass therethrough.

The beam blocking mechanism in FIGS. 5A and 5B is a shielding plate 28a having a disc shape or the like. In the blocking state of FIG. 5A, the shielding plate 28a is disposed on the beamline A and physically blocks the ion beam IB. In the non-blocking state of FIG. 5B, since the shielding plate 28a rotated around a rotation axis in a direction (for example, the x direction) perpendicular to the extending direction (z direction) of the beamline A as indicated by an arrow from the blocking state deviates from the beamline A, the ion beam IB can pass.

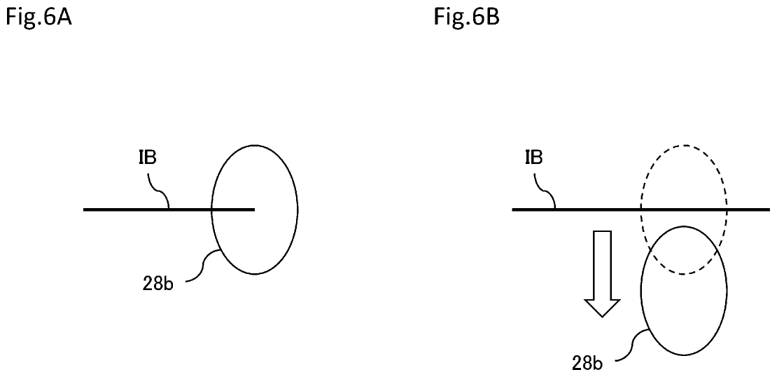

A beam blocking mechanism in FIGS. 6A and 6B is a shielding plate 28b having a disc shape or the like. In the blocking state of FIG. 6A, the shielding plate 28b is disposed on the beamline A and physically blocks the ion beam IB. In the non-blocking state of FIG. 6B, since the shielding plate 28b moved in a direction (for example, the y direction) perpendicular to the extending direction (z direction) of the beamline A as indicated by an arrow from the blocking state deviates from the beamline A, the ion beam IB can pass.

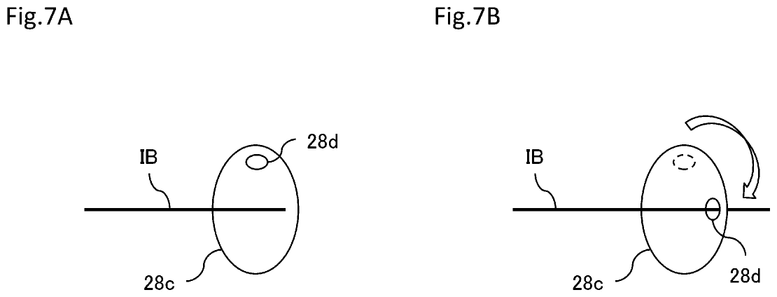

A beam blocking mechanism in FIGS. 7A and 7B is a shielding plate 28c having a disc shape or the like, and a window 28d or a hole through which the ion beam IB can pass is formed at at least one spot of the outer periphery thereof. In the blocking state of FIG. 7A, since the window 28d deviates from the beamline A, a portion of the shielding plate 28c other than the window 28d physically blocks the ion beam IB. In the non-blocking state of FIG. 7B, since the window 28d of the shielding plate 28c rotated around a rotation axis in a direction parallel to the extending direction (z direction) of the beamline A as indicated by an arrow from the blocking state is disposed on the beamline A, the ion beam IB can pass through the window 28d.

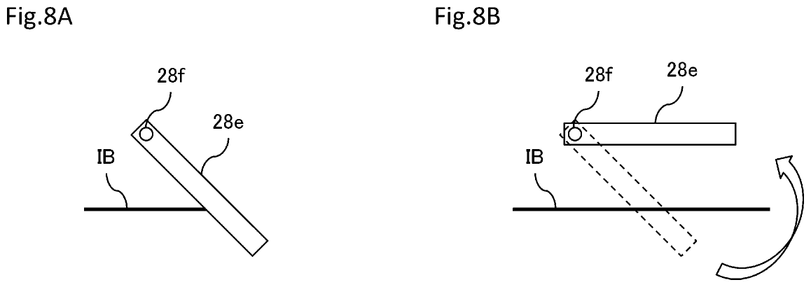

A beam blocking mechanism in FIGS. 8A and 8B is a shielding plate 28e that is a plate rotatable around a rotary shaft 28f in a direction (for example, the x direction) perpendicular to the extending direction (z direction) of the beamline A. In the blocking state of FIG. 8A, the shielding plate 28e is disposed on the beamline A and physically blocks the ion beam IB. In the non-blocking state of FIG. 8B, since the shielding plate 28e rotated around the rotary shaft 28f as indicated by an arrow from the blocking state deviates from the beamline A the ion beam IB can pass.

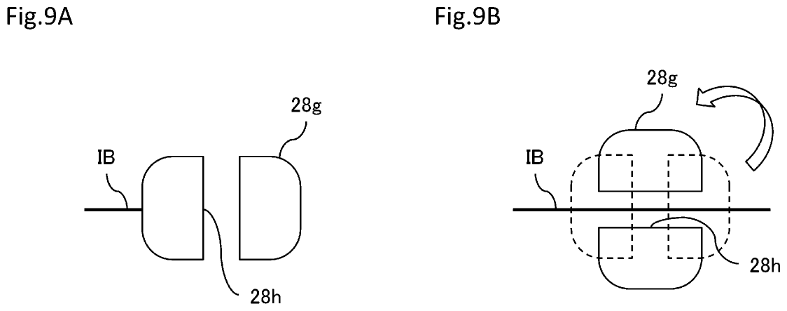

A beam blocking mechanism of FIGS. 9A and 9B is a block-shaped shield member 28g having a passage 28h through which the ion beam IB can pass. The block-shaped shield member 28g is rotatable around a rotation axis in a direction (for example, the x direction) perpendicular to the extending direction (z direction) of the beamline A. In the blocking state of FIG. 9A, since the passage 28h intersects or is perpendicular to the beamline A, a portion of the shield member 28g other than the passage 28h physically blocks the ion beam IB. In the non-blocking state of FIG. 9B, since the passage 28h of the shield member 28g rotated from the blocking state as indicated by an arrow is disposed substantially parallel to the beamline A, the ion beam IB can pass through the passage 28h.

Hereinafter, the beam blocking mechanisms of FIGS. 5 to 9 and the injector Faraday cup 28 of FIGS. 1 and 2 will be collectively referred to as a beam blocking mechanism 28.

In FIGS. 1 and 2, the beam shaping unit 30 includes a focusing/defocusing device such as a focusing/defocusing quadrupole lens (Q lens), and shapes the ion beam that has passed through the mass analyzing unit 20 into a desired cross-sectional shape. The beam shaping unit 30 composed of, for example, an electric field type three-stage quadrupole lens (also referred to as a triplet Q lens) has three quadrupole lenses 30a, 30b, and 30c. By using the three quadrupole lenses 30a, 30b, and 30c, the beam shaping unit 30 can independently adjust the convergence or divergence of the ion beam in the x direction and the y direction. The beam shaping unit 30 may include a magnetic field type lens device or may include a lens device that shapes the ion beam by utilizing both an electric field and a magnetic field.

The beam scanning device 32 performs reciprocating scanning by at least one of an electric field and a magnetic field in a predetermined scanning angle range in the x direction with an ion beam (shaped by the beam shaping unit 30) with which the wafer W is irradiated. As will be described below, the beam scanning device 32 can also be used as a beam deflection device that deflects the ion beam between the irradiation-enabled direction and the irradiation-disabled direction instead of or in addition to the beam park device 24. The beam scanning device 32 includes a pair of scanning electrodes that faces each other in a beam scanning direction (x direction). The pair of scanning electrodes is connected to a variable voltage power supply (not shown), and a voltage to be applied between the pair of scanning electrodes is periodically changed to change an electric field between the electrodes such that the ion beam is deflected at various angles in a zx plane. As a result, the entire scanning range in the x direction is scanned with the ion beam. In FIG. 1, a scanning direction and a scanning range of the ion beam are exemplified by an arrow X, and a plurality of trajectories of the ion beam in the scanning range are exemplified by one-point chain lines.

The beam parallelizing unit 34 adjusts the traveling directions of the ion beam scanned by the beam scanning device 32 to be substantially parallel to the trajectory of the designed beamline A. The beam parallelizing unit 34 includes a plurality of arc-shaped parallelizing lens electrodes in each of which an ion beam passing slit is provided at a central portion in the y direction. The parallelizing lens electrodes are connected to a high-voltage power supply (not shown), and an electric field generated by the applied voltage is made to act on the ion beam to align the traveling directions of the ion beam substantially parallel to the beamline A. In addition, the beam parallelizing unit 34 may be replaced with another type of beam parallelizing device, for example, a magnetic device using a magnetic field. Additionally, an acceleration/deceleration (AD) column (not shown) for accelerating or decelerating the ion beam may be provided downstream of the beam parallelizing unit 34.

The angular energy filter (AEF) 36 analyzes the energy of the ion beam and deflects the ions of having required energy downward (−y direction) at a prescribed angle to guide the ions to the implantation processing chamber 16. The angular energy filter 36 includes an AEF electrode pair for electric field deflection connected to a high-voltage power supply (not shown). In FIG. 2, by applying a positive voltage to an upper (+y side) AEF electrode and applying a negative voltage to a lower (−y side) AEF electrode, an ion beam having a positive charge is deflected downward (in the case of an ion beam having a negative charge, the negative voltage is applied to the upper AEF electrode and the positive voltage is applied to the lower AEF electrode). In addition, the angular energy filter 36 may be composed of a magnetic device for magnetic field deflection or may be composed of a combination of the AEF electrode pair for electric field deflection and the magnetic device for magnetic field deflection.

As described above, the beamline unit 14 supplies the ion beam, with which the wafer W serving as a workpiece is to be irradiated, to the implantation processing chamber 16. The implantation processing chamber 16 includes an energy slit 38, a plasma shower device 40, side cups 42 (42R, 42L), a profiler cup 44, and the beam stopper 46 in order from the upstream side of the beamline A. As shown in FIG. 2, the implantation processing chamber 16 includes a platen driving device 50 that holds one or a plurality of wafers W.

The energy slit 38 is provided downstream of the angular energy filter 36 and analyzes the energy of the ion beam incident into the wafer W together with the angular energy filter 36. The energy slit 38 is an energy defining slit (EDS) which is a slit horizontally long in the beam scanning direction (x direction). The energy slit 38 allows an ion beam having a desired energy value or a desired energy range to pass toward the wafer W, and shields the other ion beams.

The plasma shower device 40 is disposed downstream of the energy slit 38. The plasma shower device 40 supplies low-energy electrons to the ion beam and/or the front surface (wafer processing surface) of the wafer W depending on the amount of beam current of the ion beam and suppresses the accumulation (so-called charge-up) of positive charges on the wafer processing surface generated by ion implantation. The plasma shower device 40 includes, for example, a shower tube through which an ion beam passes and a plasma generating device that supplies electrons into the shower tube.

The side cups 42 (42R, 42L) measure the beam current of the ion beam during ion implantation processing into the wafer W. As shown in FIG. 1, the side cups 42R and 42L are disposed so as to be deviated from the wafer W disposed on the beamline A to the left and right (x direction) and are disposed at positions where the ion beam directed to the wafer W are not blocked during ion implantation. Since the scanning in the x direction is performed with the ion beam beyond a range where the wafer W is located, a part of the scanning beam is incident into the side cups 42R and 42L even during the ion implantation. In this way, the amount of beam current during the ion implantation processing is measured with the side cups 42R and 42L. Since the wafer W serving as a workpiece is not irradiated with the ion beam incident into the side cups 42R and 42L during the ion implantation, the side cups 42R and 42L constitute a second beam current measuring device (a first beam current measuring device will be described below) that measures the beam current of the ion beam directed in the irradiation-disabled direction in which the wafer W cannot be irradiated with the ion beam. In addition, a beam current measuring device such as a Faraday cup may be provided on the beam dump 26 with which the ion beam directed in the irradiation-disabled direction collides, and may serve as the second beam current measuring device.

The profiler cup 44 measures a beam current on the wafer processing surface. The profiler cup 44 is movable in the x direction by the operation of a drive unit 45, is retreated from an implantation region where the wafer W is located during the ion implantation, and is inserted into the implantation region when the wafer W is not located in the implantation region. The profiler cup 44 driven in the x direction can measure the beam current over an entire beam scanning range in the x direction. The profiler cup 44 may include a plurality of Faraday cups that are arranged in the x direction so that the beam currents at a plurality of positions in the beam scanning direction (x direction) can be simultaneously measured. Since the ion beam incident into the profiler cup 44 is incident into the implantation region where the wafer W serving as the workpiece is located during the ion implantation, the profiler cup 44 constitutes a first beam current measuring device that measures the beam current of the ion beam directed in the irradiation-enabled direction in which the wafer W can be irradiated. In addition, a beam current measuring device such as a Faraday cup may be provided on the beam stopper 46 with which the ion beam directed in the irradiation-enabled direction collides, and may serve as the first beam current measuring device.

The profiler cup 44 includes a first profiler cup 44a and a second profiler cup 44b. The first profiler cup 44a is a first Faraday cup for normal measurement to be used in a preparation process prior to an implantation process. The second profiler cup 44b is a second Faraday cup for calibration to be used in a calibration process. A shielding member 43 is provided in front of the second profiler cup 44b so that the ion beam cannot be incident into the second profiler cup 44b in the implantation process and the preparation process. In addition, the shielding member 43 may not be a dedicated member for blocking the incidence of the ion beam into the second profiler cup 44b, and may be a part or the whole of any structure provided in the implantation processing chamber 16.

The second profiler cup 44b may have higher measurement accuracy than the first profiler cup 44a. For example, as components of the second profiler cup 44b are machined with higher accuracy than those of the first profiler cup 44a, the tolerance in the size of an opening into which the ion beam to be measured is incident is reduced. Additionally, the second profiler cup 44b may be slower in degradation in measurement accuracy caused by use than the first profiler cup 44a. For example, the second profiler cup 44b may be configured with components having higher wear resistance than the first profiler cup 44a.

The first profiler cup 44a and the second profiler cup 44b can be driven by the drive unit 45 independently of each other. The first profiler cup 44a is movable in the x direction along a first drive shaft 45a of the drive unit 45. The second profiler cup 44b is movable in the x direction along a second drive shaft 45b of the drive unit 45. The movement directions of the first profiler cup 44a and the second profiler cup 44b are substantially parallel to each other.

At least one of the side cups 42 and the profiler cup 44 may include a single Faraday cup for measuring the amount of beam current or may include an angle measuring instrument for measuring the angle information of the ion beam. The angle measuring instrument includes, for example, a slit and a plurality of current detecting units provided apart from the slit in the beam traveling direction (z direction). The angle measuring instrument can measure the angle component or angle distribution of the beam in the slit width direction by measuring the ion beam passed through the slit with the plurality of current detecting units lined up in the slit width direction. At least one of the side cups 42 and the profiler cup 44 may include a first angle measuring instrument capable of measuring angle information in the x direction and/or a second angle measuring instrument capable of measuring angle information in the y direction.

The platen driving device 50 includes a wafer holding device 52, a reciprocating mechanism 54, a twist angle adjustment mechanism 56, and a tilt angle adjustment mechanism 58.

The wafer holding device 52 for holding the wafer W irradiated with the ion beam constitutes a support mechanism that supports the wafer W, and includes an electrostatic chuck as an electrostatic holding mechanism that holds the supported wafer W by electrostatic attraction. The wafer holding device 52 may include a temperature adjusting device for heating or cooling the wafer W into which ions are implanted. The temperature adjusting device may be a heating device that heats the wafer W to a temperature higher than the room temperature by +20° C. or higher, +50° C. or higher, and +100° C. or higher, or may be a cooling device that cools the wafer W to a lower temperature that is a temperature lower than the room temperature by −20° C. or lower, −50° C. or lower, and −100° C. or lower. The temperature of the wafer W affects the concentration distribution (implantation profiler) of ions implanted into the wafer W and the state of crystal defects (implantation damage) formed in the wafer W by the ion implantation. The processing of irradiating the wafer W having a temperature higher than room temperature with the ion beam is also referred to as high-temperature implantation. Additionally, the processing of irradiating the wafer W having a temperature lower than room temperature with the ion beam is also referred to as low-temperature implantation.

The reciprocating mechanism 54 is a drive mechanism that reciprocates the wafer holding device 52 including the support mechanism in a direction intersecting the ion beam. The reciprocating mechanism 54 reciprocates the wafer W held by the wafer holding device 52 in the y direction by reciprocating the wafer holding device 52 including a support mechanism in a reciprocating motion direction (y direction) perpendicular to the beam scanning direction (x direction). In FIG. 2, a direction and a range of the reciprocating motion of the wafer W are exemplified by an arrow Y.

The twist angle adjustment mechanism 56 constituting an implantation angle adjustment mechanism is a mechanism that adjusts the rotation angle of the wafer W, and adjusts the twist angle between an alignment mark provided at an outer peripheral portion of the wafer W and a reference position by rotating the wafer W with a normal line perpendicular to the wafer processing surface as a rotation axis at the center of the wafer processing surface. Here, the alignment mark of the wafer W is, for example, a notch or an orientation flat provided at an outer peripheral portion of the wafer W and serves as a reference for an angular position in the crystal direction of the wafer W or in the circumferential direction of the wafer W. The twist angle adjustment mechanism 56 is provided between the wafer holding device 52 and the reciprocating mechanism 54 and is reciprocated by the reciprocating mechanism 54 together with the wafer holding device 52.

The tilt angle adjustment mechanism 58 constituting the implantation angle adjustment mechanism is a mechanism that adjusts the tilt of the wafer W and adjusts the tilt angle between the traveling direction of the ion beam directed to the wafer processing surface and the normal line of the wafer processing surface. In the example of FIG. 2, out of a plurality of inclination angles of the wafer W, a rotation angle with the axis in the x direction as a center axis of rotation is adjusted as the tilt angle of the wafer W by the tilt angle adjustment mechanism 58. The tilt angle adjustment mechanism 58 is provided between the reciprocating mechanism 54 and an inner wall of the implantation processing chamber 16 and adjusts the tilt angle of the wafer W by rotating the entire platen driving device 50 including the reciprocating mechanism 54 in an R direction (FIG. 2).

The platen driving device 50 holds the wafer W such that the wafer W is movable between the ion implantation position where the wafer W is irradiated with the ion beam and a transfer position where the wafer W is transferred to or from the wafer transfer device 18. That is, the platen driving device 50 constitutes a moving device that moves the wafer holding device 52 between the ion implantation position where the wafer W supported with the wafer holding device 52 is irradiated with the ion beam, and the transfer position where the wafer transfer device 18 can transfer the wafer W to or from the wafer holding device 52. FIG. 2 shows a state in which the wafer W and the wafer holding device 52 are at the ion implantation position, and the wafer holding device 52 holds the wafer W so as to intersect the beamline A. The transfer position of the wafer W corresponds to the position of the wafer holding device 52 when the wafer W is transferred through a transfer port 48 by a transfer mechanism or a transfer robot provided in the wafer transfer device 18.

The beam stopper 46 is provided on the most downstream side of the beamline A and is mounted on, for example, the inner wall of the implantation processing chamber 16. An ion beam in a case where the wafer W and the profiler cup 44 are not present on the beamline A is incident into the beam stopper 46. The beam stopper 46 is disposed near the transfer port 48 that connects the implantation processing chamber 16 and the wafer transfer device 18 to each other, and is provided at a position vertically below (−y direction) the transfer port 48 in the example of FIG. 2.

The beam stopper 46 is mounted on a plurality of tuning cups 47 (47a, 47b, 47c, and 47d). Each tuning cup 47 is a Faraday cup that measures a beam current of a part of an ion beam incident into the beam stopper 46. The plurality of tuning cups 47 are disposed apart from each other in the x direction. For example, each tuning cup 47 is used to simply measure the beam current at the ion implantation position regardless of the profiler cup 44. When the wafer W is irradiated with a part of the ion beam, the tuning cups 47 and/or the above-mentioned side cups 42 constitutes a beam current measuring device for dose control that measures, as a beam current, another portion of the ion beam with which the wafer W is not irradiated.

The ion implanter 10 further includes a control device 60 that controls the overall operation thereof. The control device 60 is realized by the cooperation between hardware resources such as a central arithmetic processing device of a computer, a memory, an input device, an output device, and peripheral units connected to a computer, and software executed using the hardware resources. Regardless of the type and installation location of the computer, each function of the control device 60 may be realized by the hardware resources of a single computer, or may be realized by combining the hardware resources distributed to a plurality of computers. Details of the control device 60 will be described below.

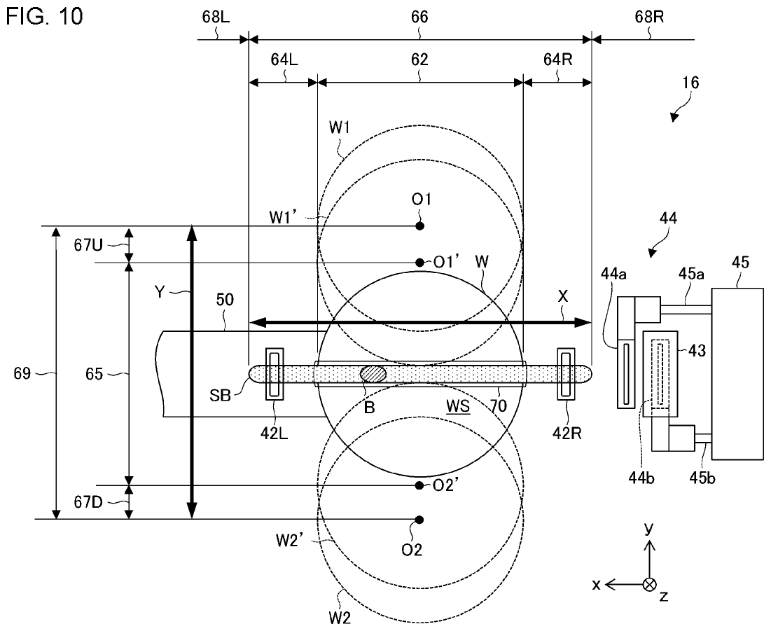

FIG. 10 is a front view of a processing target surface WS of the wafer W irradiated with an ion beam B as viewed from the front (from a −z direction), and shows a schematic configuration inside the implantation processing chamber 16. The reciprocating scanning is performed with the ion beam B in the x direction by the beam scanning device 32 as indicated by an arrow X, and the ion beam B constitutes a scan beam SB with which the irradiation range 66 extending in the x direction is sequentially irradiated. Here, an ion implantation position 70 in which the scan beam SB is incident into the processing target surface WS of the wafer W and ions are implanted in the implantation process is shown by a fine solid line.

An irradiation range 66 including an implantation range 62 where the wafer W is located and monitoring ranges 64R and 64L outside the implantation range 62 are reciprocally scanned with the ion beam B. The above-mentioned right and left side cups 42R and 42L are disposed in the right and left monitoring ranges 64R and 64L. The right and left side cups 42R and 42L can measure the ion beam B with which the monitoring ranges 64R and 64L are overscanned during the implantation process. The range of the ion implantation position 70 in the x direction coincides with the implantation range 62. The range of the ion implantation position 70 in the y direction coincides with the irradiation range of the ion beam B or the scan beam SB in the y direction. The position of the ion implantation position 70 in the z direction coincides with the position of the processing target surface WS of the wafer W in the z direction.

The above-mentioned profiler cup 44 is retreated to a non-irradiation range 68 (68R, 68L) outside the irradiation range 66 in the implantation process. In a shown example in which the drive unit 45 is disposed on the right side, the first profiler cup 44a and the second profiler cup 44b are retreated to the non-irradiation range 68R on the right side in the implantation process. In addition, in a case where the drive unit 45 is disposed on the left side, the first profiler cup 44a and the second profiler cup 44b may be retreated to the non-irradiation range 68L on the left side in the implantation process.

The above-mentioned shielding member 43 is also provided in the non-irradiation range 68R on the right side and is disposed so as to overlap the second profiler cup 44b in the beam traveling direction (z direction). In other words, the ranges of the shielding member 43 in directions (the x direction and the y direction) perpendicular to the beam traveling direction at least partially overlap the ranges of the second profiler cup 44b in the directions perpendicular to the beam traveling direction. The shielding member 43 shields the ion beam B directed to the second profiler cup 44b except for the calibration process. Since the ion beam B cannot be incident into the second profiler cup 44b by the shielding member 43 except for the calibration process, it is possible to prevent the second profiler cup 44b from being consumed or soiled by the ion beam B.

The wafer W (W1, W1′, W2, W2′) is reciprocally driven in the y direction by the reciprocating mechanism 54 of the platen driving device 50 as indicated by an arrow Y, and sequentially moves within a reciprocation range 69 extending in the y direction. Here, the reciprocation range 69 is, for example, a range in the y direction through which a center (O1, O1′, O2, O2′) of the processing target surface WS of the wafer W passes. The position of an upper end of the reciprocation range 69 in the y direction corresponds to the position, in the y direction, of the center O1 of the wafer W1 that has moved to an upper reversing end, and the position of a lower end of the reciprocation range 69 in the y direction corresponds to the position, in the y direction, of the center O2 of the wafer W2 that has moved to a lower reversing end.

The reciprocation range 69 includes a beam irradiation range 65 in which at least a part of the processing target surface WS of the wafer W is irradiated with the ion beam B, and a beam non-irradiation range 67 (67U, 67D) which is adjacent to at least one end of the beam irradiation range 65 and in which the processing target surface WS of the wafer W is not irradiated with the ion beam B. In the example of FIG. 10, the beam non-irradiation range 67 includes a first beam non-irradiation range 67U adjacent to an upper end of the beam irradiation range 65 and a second beam non-irradiation range 67D adjacent to a lower end of the beam irradiation range 65.

Here, an upper end of the first beam non-irradiation range 67U coincides with an upper reversing end of the reciprocation range 69, and a lower end of the first beam non-irradiation range 67U (the upper end of the beam irradiation range 65) corresponds to, for example, the position, in the y direction, of a center O1′ of the processing target surface WS when a lower end of a wafer W1′ is separated upward from the ion implantation position 70. Additionally, a lower end of the second beam non-irradiation range 67D coincides with a lower reversing end of the reciprocation range 69, and an upper end of the second beam non-irradiation range 67D (the lower end of the beam irradiation range 65) corresponds to, for example, the position, in the y direction, of a center O2′ of the processing target surface WS when a upper end of a wafer W2′ is separated downward from the ion implantation position 70.

Subsequently, the implantation process, the preparation process, and the calibration process of the ion implanter 10 to be executed under the control of the control device 60 will be described.

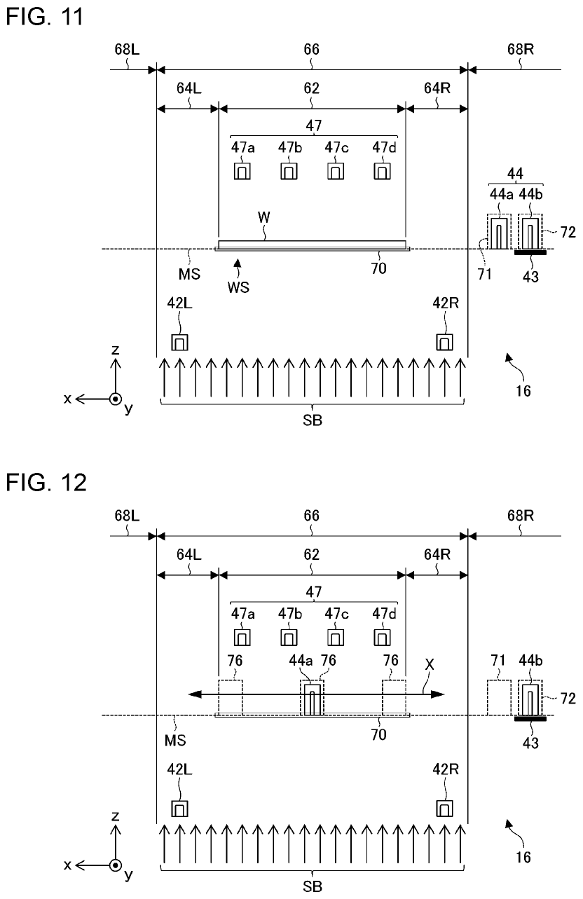

FIG. 11 is a top view schematically showing the inside of the implantation processing chamber 16 in the implantation process. In the implantation process, the wafer W is disposed in the implantation range 62, and the profiler cup 44 is disposed in the non-irradiation range 68. The first profiler cup 44a is disposed at a first retreat position 71 shown by a broken line, and the second profiler cup 44b is disposed at a second retreat position 72 shown by a broken line. The first retreat position 71 and the second retreat position 72 are adjacent to each other in the x direction within the non-irradiation range 68R on the right side. The first retreat position 71 is located on the left side closer to the ion implantation position 70 than the second retreat position 72. The shielding member 43 is disposed so as to close the entrance of the second profiler cup 44b located at the second retreat position 72.

In the implantation process, beam currents can always be measured with the side cups 42R and 42L. On the other hand, the profiler cup 44a and the tuning cups 47 in the implantation process can only intermittently measure the beam currents. For this reason, in the implantation process, the dose of the ions to be implanted into the processing target surface WS of the wafer W is controlled on the basis of the beam current values measured with the side cups 42R and 42L. In a case where the beam current values measured with the side cups 42R and 42L change during the implantation process, the dose distribution in the processing target surface WS of the wafer W is adjusted by changing the speed of the reciprocating motion of the wafer W in the y direction with the reciprocating mechanism 54. For example, in a case where it is desired to realize a uniform dose distribution in the processing target surface WS, the wafer W is reciprocated at a speed proportional to the beam current values monitored by the side cups 42R and 42L. Specifically, in a case where the monitored beam current values increase, the speed of the reciprocating motion of the wafer W is increased, and in a case where the monitored beam current values decrease, the speed of the reciprocating motion of the wafer W is decreased. Accordingly, it is possible to prevent a variation in the dose in the processing target surface WS resulting from a fluctuation in the beam current of the scan beam SB. In addition, in a case where the beam current values measured with the side cups 42R and 42L deviate from predetermined current values by, for example, ±10% or more, the ion implanter 10 may be stopped as an abnormal state.

In the implantation process, the control device 60 acquires the beam current values measured with the side cups 42R and 42L, and controls the operation of the platen driving device 50 on the basis of the acquired beam current values. For example, the control device 60 generates a speed command for the platen driving device 50 such that the wafer W reciprocates in the y direction at a speed proportional to the beam current values acquired from the side cups 42R and 42L.

FIG. 12 is a top view schematically showing the inside of the implantation processing chamber 16 in the preparation process. In the preparation process executed before the implantation process, the beam currents of the scan beam SB are measured over the implantation range 62 and the monitoring ranges 64R and 64L (that is, the entire irradiation range 66). The beam current in the implantation range 62 is measured with the first profiler cup 44a and/or the tuning cups 47. The beam currents in the monitoring ranges 64R and 64L are measured with the side cups 42R and 42L, similarly to the implantation process.

In the preparation process, the first profiler cup 44a moves from the first retreat position 71 to one or a plurality of first measurement positions 76 in the x direction. Each of the first measurement positions 76 overlaps the ion implantation position 70 (or the implantation range 62) in the beam traveling direction (z direction) and is located on a plane (hereinafter, also referred to as a measurement surface MS) that coincides with the processing target surface WS in the implantation process. Therefore, the first profiler cup 44a can measure the beam current at the first measurement position 76 included in the ion implantation position 70 where ions are implanted into the wafer W in the implantation process. The first profiler cup 44a may acquire the beam current distribution in the x direction at the ion implantation position 70 (or the measurement surface MS) by measuring the beam current while moving among the plurality of first measurement positions 76 in the x direction.

Similarly to the first measurement position 76, the plurality of tuning cups 47 overlap the ion implantation position 70 (or the implantation range 62) in the beam traveling direction (z direction), but are separated to the downstream side (on the +z direction side) from the ion implantation position 70 (or the measurement surface MS). Since the plurality of tuning cups 47 do not need to be moved between the retreat position and the measurement position unlike the first profiler cup 44a, the beam current in the implantation range 62 can be more simply and easily measured as compared to the first profiler cup 44a.

In the preparation process, the control device 60 acquires beam current values measured with various Faraday cups in the implantation processing chamber 16, specifically, the side cups 42R and 42L, the first profiler cup 44a, and the plurality of tuning cups 47. The control device 60 stores a ratio between the respective beam current values acquired from the respective Faraday cups, and calculates a desired beam current value in the implantation range 62 (the ion implantation position 70 or the processing target surface WS) on the basis of the beam current values in the monitoring ranges 64R and 64L measured with the side cups 42R and 42L in the implantation process. Normally, the ratio between the respective beam current values measured with the respective Faraday cups depends on the configuration and setting of an optical system of the beamline unit 14, and is almost constant even when the beam current of the ion beam B extracted from the ion generation device 12 fluctuates slightly. That is, when the configuration and setting of the optical system of the beamline unit 14 is determined in the preparation process, the ratio between the beam current values remains almost unchanged even in the subsequent implantation process. Therefore, the beam current value in the ion implantation position 70 (the implantation range 62 or the processing target surface WS) where ions are implanted into the wafer W in the implantation process can be calculated on the basis of the ratio between the beam current values stored in the preparation process and the beam current values measured with the side cups 42R and 42L in the implantation process.

In addition, the second profiler cup 44b is not used in the implantation process in FIG. 11 and the preparation process in FIG. 12. The second profiler cup 44b stays at the second retreat position 72 where the scan beam SB is blocked by the shielding member 43 throughout the preparation process and the implantation process. The second profiler cup 44b is used in the calibration process for calibrating the measurement value of the beam current of the first profiler cup 44a. The calibration process is executed at the time of starting the operation of an unused ion implanter 10, or at the time of maintenance for cleaning or replacement of the first profiler cup 44a.

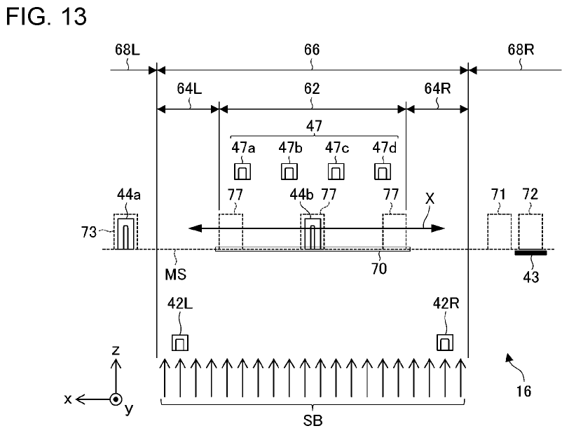

FIG. 13 is a top view schematically showing the inside of the implantation processing chamber 16 in the calibration process. In the calibration process, the second profiler cup 44b moves from the second retreat position 72 to one or a plurality of the second measurement positions 77 in the x direction. Similarly to each first measurement position 76, each second measurement position 77 overlaps the ion implantation position 70 (or the implantation range 62) in the beam traveling direction (z direction) and is located on a plane (the measurement surface MS) that coincides with the processing target surface WS in the implantation process. Each second measurement position 77 coincides with each first measurement position 76 at least partially. The second profiler cup 44b can measure the beam current at the same position as that of the processing target surface WS in the implantation process and can measure the beam current at the same position as that of the first profiler cup 44a in the preparation process. The second profiler cup 44b may acquire the beam current distribution in the x direction at the ion implantation position 70 (or the measurement surface MS) by measuring the beam current while moving among the plurality of second measurement positions 77 in the x direction.

The first profiler cup 44a in the calibration process may be disposed at a third retreat position 73 different from the first retreat position 71. In the shown example, the third retreat position 73 is located within the non-irradiation range 68L on the left side. In this case, the third retreat position 73 is located on a side opposite to the first retreat position 71 and the second retreat position 72 across the implantation range 62. By retreating the first profiler cup 44a to the third retreat position 73, the second profiler cup 44b does not interfere with the first profiler cup 44a when moving from the second retreat position 72 to the second measurement position 77.

In the calibration process, the first profiler cup 44a and the second profiler cup 44b may be driven separately or independently or may be driven simultaneously. In the case of the former independent driving, first, the first profiler cup 44a is first moved to at least one of the measurement positions 76, and the beam current value at the ion implantation position 70 is measured. Subsequently, the second profiler cup 44b is moved to at least one of the second measurement positions 77, and the beam current value at the ion implantation position 70 is measured. Additionally, in the case of the simultaneous driving, the beam current value is measured at one or a plurality of first measurement positions 76 while the first profiler cup 44a moves in the x direction from the first retreat position 71 toward the third retreat position 73. Simultaneously with this, the second profiler cup 44b moves from the second retreat position 72 to at least one of the second measurement positions 77 to measure the beam current value. By operating the profiler cup 44 as described above, the scan beam SB can be measured under the same conditions at the same measurement position at the ion implantation position 70 by the first profiler cup 44a and the second profiler cup 44b.

The control device 60 determines a calibration parameter for calibrating the measurement value of the first profiler cup 44a on the basis of the beam current values measured with the first profiler cup 44a and the second profiler cup 44b. In a case where a first beam current measurement value acquired by the first profiler cup 44a in the calibration process is I1 and a second beam current measurement value acquired by the second profiler cup 44b in the calibration process is I2, a calibration parameter k is represented by a ratio I2/I1 between the first beam current measurement value I1 and the second beam current measurement value I2 (k=I2/I1). The calibrated beam current value I2 with the second profiler cup 44b as a reference can be calculated by I2=k×I1 depending on the calibration parameter k on the basis of the beam current measurement value I1 acquired by the first profiler cup 44a in the preparation process. In the implantation process, the dose of ions on the processing target surface WS of the wafer W is controlled with reference to the beam current value k×I1 calibrated by the calibration parameter k.

Subsequently, the implantation angle adjustment mechanism configured by the twist angle adjustment mechanism 56 and the tilt angle adjustment mechanism 58 will be described. The implantation angle adjustment mechanism adjusts the implantation angle of the wafer W supported with the wafer holding device 52 with respect to the ion beam. In the present embodiment, a plurality of ion implantation processes having different implantation conditions (implantation angles) are continuously executed on the same wafer W. Hereinafter, an example will be described in which the implantation angle adjustment mechanism adjusts the implantation angle in four ways and continuously executes the four ion implantation processes at respective implantation angles on the same wafer W. Each implantation angle is determined depending on a set of a constant tilt angle θ that is set by the tilt angle adjustment mechanism 58 and is not 0 degrees, and each of four twist angles φ (for example, 0 degrees, 90 degrees, 180 degrees, and 270 degrees) that are set by the twist angle adjustment mechanism 56 and are different from each other. In addition, in the respective ion implantation processes having different implantation angles, the dose distribution in the processing target surface WS of the wafer W may be set to have a desired non-uniform shape, and the ion implantation conditions may be set such that the current density distribution of an ion beam changes with which each region in the processing target surface WS is irradiated.

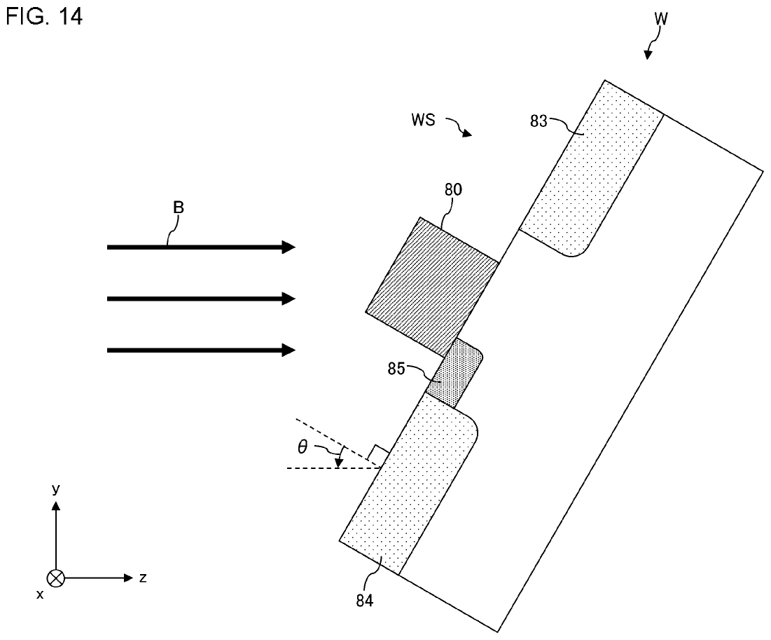

FIG. 14 is a diagram schematically showing an implantation process with a non-zero tilt angle θ. Here, an aspect is shown in which the wafer W in which a gate 80, a drain region 83, and a source region 84 are formed on the processing target surface WS is tilted at a tilt angle θ with respect to the ion beam B, and the ion beam B with which a lower portion of the gate 80 is irradiated is used forms a halo implantation region 85. The tilt angle θ of the wafer W is set to several degrees or more, preferably ten degrees or more such that the lower portion of the gate 80 is effectively irradiated with the ion beam B. In addition, such a “non-zero tilt angle implantation process” may be executed in order to form an optional ion implantation region different from the halo implantation region.

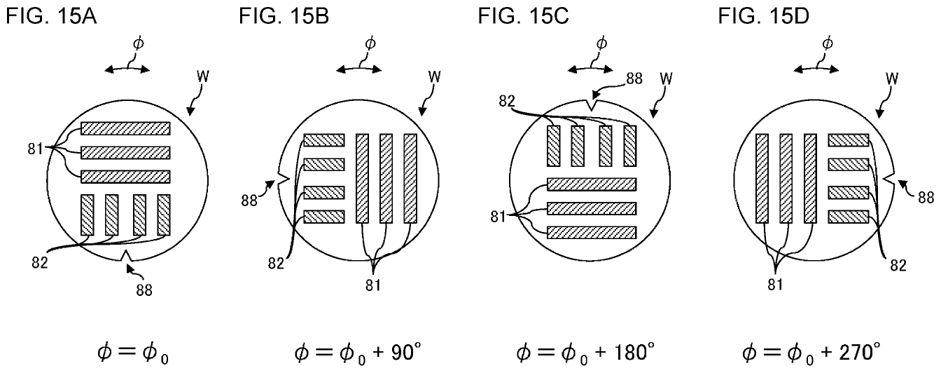

FIGS. 15A to 15D schematically show changes in a twist angle φ by the twist angle adjustment mechanism 56. The twist angle φ is a rotation angle of the wafer W about a normal line (a straight line perpendicular to a paper surface in FIGS. 15A to 15D) passing through the center of the processing target surface of the wafer W as a rotation axis. The twist angle φ corresponds to, for example, a rotation position (notch position) of an alignment mark 88 provided at an outer peripheral portion of the wafer W. Assuming that the twist angle φ in a state where the alignment mark 88 is at a lower end of the wafer W is φ₀ in FIG. 15A, the twist angle φ in a state in which the alignment mark 88 is at a left end of the wafer W is φ₀+90 degrees in FIG. 15B, the twist angle φ in a state in which the alignment mark 88 is at an upper end of the wafer W is φ₀+180° degrees in FIG. 15C, and the twist angle φ in a state in which the alignment mark 88 is at a right end of the wafer W is φ₀+270 degrees in FIG. 15D. In addition, in FIGS. 15A to 15D, a gate 81 extending in a first direction and a gate 82 extending in a second direction perpendicular to the first direction are formed on the processing target surface of the wafer W. The wafer W is sequentially switched to four twist angles φ₀, φ₀+90 degrees, φ₀+180 degrees, and φ₀+270 degrees by the twist angle adjustment mechanism 56, and the four ion implantation processes are continuously executed at the respective twist angles φ on the same wafer W.

Hereinafter, when the twist angle adjustment mechanism 56 switches the twist angle φ of the wafer W, the twist angle φ before the switching is collectively referred to as a first twist angle φ1, and the twist angle φ after the switching is collectively referred to as a second twist angle φ2. Additionally, the implantation angle at the first twist angle φ1 (and the predetermined tilt angle θ₀) is collectively referred to as a first implantation angle, and the implantation angle at the second twist angle φ2 (and the predetermined tilt angle θ₀) is collectively referred to as a second implantation angle. A difference between the first twist angle φ1 and the second twist angle φ2 is preferably greater than 0 degrees and 180 degrees or less. In the example of FIGS. 15A to 15D, in a case where the twist angle φ is sequentially switched as in (a)→(b)→(c)→(d), the difference between the first twist angle φ1 and the second twist angle φ2 is constant at 90 degrees. In this way, in a case where N twist angles φ (N is a natural number of 2 or more, and N=4 in FIG. 15) are applied to the same wafer W, the difference between the first twist angle φ1 and the second twist angle φ2 is preferably the same for all N times (constant at 90 degrees in FIG. 15). In this case, the difference between the first twist angle φ1 and the second twist angle φ2 is an angle obtained by dividing 360 degrees by N (360 degrees÷4=90 degrees in FIG. 15). Additionally, an applicable number N for the twist angle φ is preferably an even number of 2 or more and 32 or less.

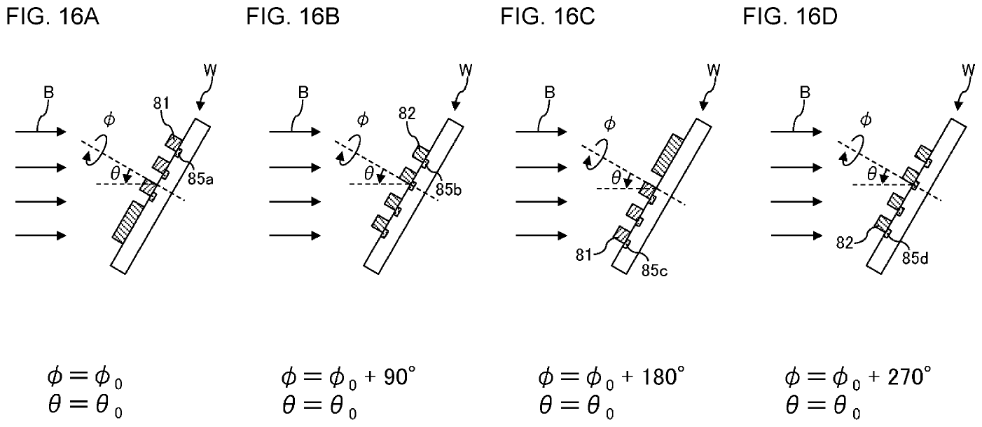

FIGS. 16A to 16D schematically show non-zero tilt angle implantation processes in which twist angles φ are different from each other as in FIGS. 15A to 15D. By executing the four implantation processes while switching the twist angle φ as shown in FIGS. 15A to 15D in a state where the tilt angle θ of the wafer W is maintained at a non-zero θ₀, it is possible to form halo implantation regions 85a to 85d directly below both the gate 81 and the gate 82 having mutually different extension directions.

In FIG. 16A, by setting to the twist angle φ₀ at which the extension direction (first direction) of the gate 81 is the x direction, the first halo implantation region 85a is formed in one adjacent region (a lower left region of the gate 81 in FIG. 16A) of the gate 81. In FIG. 16B, by switching to the twist angle φ₀+90 degrees at which the extension direction (second direction) of the gate 82 is the x direction, the second halo implantation region 85b is formed in one adjacent region (a lower left region of the gate 82 in FIG. 16B) of the gate 82. In FIG. 16C, by switching to the twist angle φ₀+180 degrees at which the extension direction (first direction) of the gate 81 is the x direction opposite to that in FIG. 16A, the third halo implantation region 85c is formed in the other adjacent region (a lower left region of the gate 81 in FIG. 16C and an upper right region of the gate 81 in FIG. 16A) of the gate 81. In FIG. 16D, by switching to the twist angle φ₀+270 degrees at which the extension direction (second direction) of the gate 82 is the x direction opposite to that in FIG. 16B, the fourth halo implantation region 85d is formed in the other adjacent region (a lower left region of the gate 82 in FIG. 16D and an upper right region of the gate 82 in FIG. 16B) of the gate 82.

As described above, by executing the plurality of non-zero tilt angle implantation processes while changing the twist angle φ, the halo implantation regions can be formed at positions corresponding to the drain region and the source region on both sides of the gate extending in different directions.

In FIGS. 14 to 16D, the implantation angle of the wafer W is switched by a set of the tilt angle θ set by the tilt angle adjustment mechanism 58 and the twist angle φ set by the twist angle adjustment mechanism 56. However, the implantation angle of the wafer W may be switched depending on other parameters. For example, in FIG. 10, the implantation angle of the wafer W may be switched by a set of rotation angles around two rotation axes (for example, a rotation axis in an up-down direction (y direction) and a rotation axis in a right-left direction (x direction) in FIG. 10) intersecting each other in the processing target surface WS (in a paper surface in FIG. 10) of the wafer W.

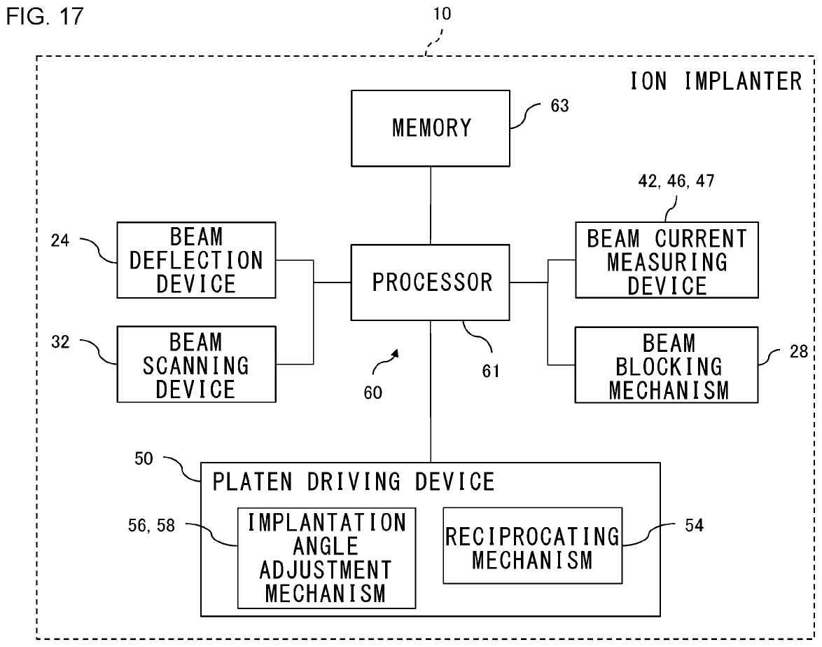

FIG. 17 is a functional block diagram of the ion implanter 10. The control device 60 of the ion implanter 10 includes a processor 61 and a memory 63. The processor 61 controls respective units of the ion implanter 10 such as the beam deflection device 24 (the beam park device 24 and the like), the beam blocking mechanism 28 (the injector Faraday cup 28 and the like), the beam scanning device 32, the beam current measuring devices 42, 44, and 47 (the side cups 42, the profiler cup 44, the tuning cups 47, and the like), the platen driving device 50 (including the implantation angle adjustment mechanism configured by the twist angle adjustment mechanism 56 and the tilt angle adjustment mechanism 58, and the reciprocating mechanism 54), and the like. The memory 63 stores a program to be executed by the processor 61. The processor 61 controls the respective units of the ion implanter 10 on the basis of the program stored in the memory 63, and executes the following series of steps.

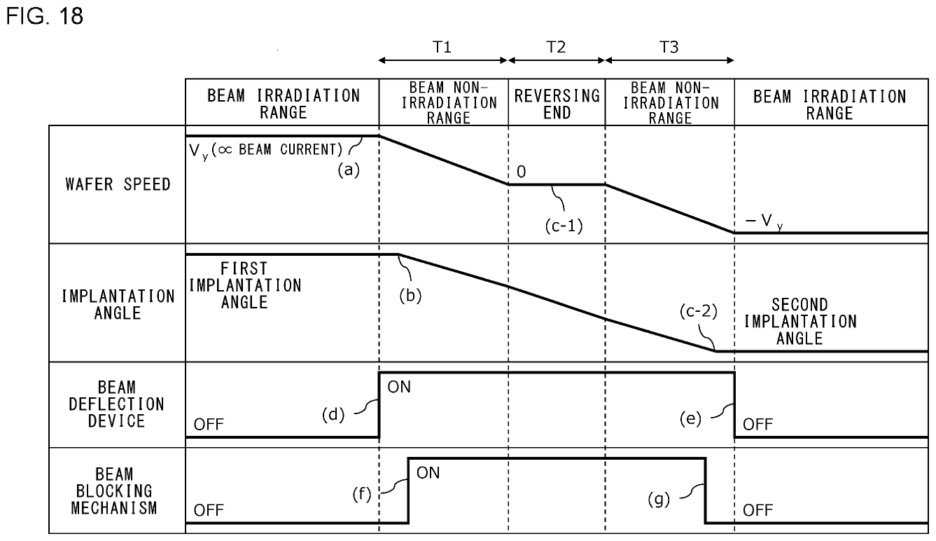

FIG. 18 is a timing chart schematically showing a basic operation in the implantation process of the ion implanter 10 to be executed by the processor 61 on the basis of the program stored in the memory 63. Respective rows in FIG. 18 schematically show a speed, in the y direction, of the wafer W as a workpiece of the ion implanter 10, an implantation angle of the wafer W by the implantation angle adjustment mechanism, and operating states of the beam deflection device 24 and the beam blocking mechanism 28.

Additionally, respective columns in FIG. 18 show a series of steps constituting the basic operation of the ion implanter 10 over time. Respective steps correspond to positions or ranges of the wafer W in the y direction in FIG. 10. Specifically, in order from the left in FIG. 18, the wafer W moves toward the one beam non-irradiation range 67 within the beam irradiation range 65 in a “BEAM IRRADIATION RANGE” in a first column, the wafer W moves toward a reversing end of the reciprocation range 69 within the one beam non-irradiation range 67 in a “BEAM NON-IRRADIATION RANGE” in a second column, the wafer W stops at the reversing end of the reciprocation range 69 at a “REVERSING END” in a third column, the wafer W moves toward the beam irradiation range 65 within the one beam non-irradiation range 67 in a “BEAM NON-IRRADIATION RANGE” in a fourth column, and the wafer W moves toward the other beam non-irradiation range 67 within the beam irradiation range 65 in a “BEAM IRRADIATION RANGE” in a fifth column.

In the step (a) in the “BEAM IRRADIATION RANGE” in the first column of FIG. 18, the processor 61 moves the wafer W, which is adjusted to have the first implantation angle by the implantation angle adjustment mechanism, from the beam irradiation range 65 toward the one beam non-irradiation range 67 (67U or 67D) by the reciprocating mechanism 54. The first implantation angle corresponds to, for example, the state of FIG. 16A, and the wafer W moving within the beam irradiation range 65 at the twist angle φ₀ and the tilt angle θ₀ is irradiated with the ion beam B. A speed v_{y}, in the y direction, of the wafer W in this “BEAM IRRADIATION RANGE” may be constant, and may be a speed controlled in accordance with the beam current values measured with the beam current measuring devices 42, 44, or 47 in order to realize a uniform dose distribution as described with respect to the implantation process in FIG. 11. For example, the magnitude of v_{y} is proportional to the beam current values measured with the side cups 42R and 42L in the implantation process. Alternatively, the magnitude of v_{y} may be controlled in accordance with the measured beam current values and the position of the wafer W in the y direction in order to realize a desired dose non-uniformity in a wafer processing target surface.

In the step (b) in the “BEAM NON-IRRADIATION RANGE” in the second column of FIG. 18, the processor 61 starts the change of the wafer W from the first implantation angle to the second implantation angle with the implantation angle adjustment mechanism while the wafer W at the first implantation angle moves within the one beam non-irradiation range 67 after having moved from the beam irradiation range 65 to the one beam non-irradiation range 67 with the reciprocating mechanism 54, subsequently to the step (a). As shown in the drawing, the step (b) may be executed after a predetermined time lapse after the wafer W enters the one beam non-irradiation range 67 or may be executed immediately after the wafer W has entered the one beam non-irradiation range 67. In addition, the step (b) for switching the implantation angle of the wafer W may be executed each time the wafer W enters the beam non-irradiation range 67 or may be executed in the beam non-irradiation range 67 that the wafer W enters after having performed the movement of the wafer W within the beam irradiation range 65 predetermined multiple times.

Here, the fact that the wafer W has entered the beam non-irradiation range 67 may be detected by the tuning cups 47 in FIG. 11. At least one of the tuning cups 47 is shielded by the wafer W while the wafer W is within the beam irradiation range 65. On the other hand, the scan beam SB is incident into all the tuning cups 47 after the wafer W has moved to the beam non-irradiation range 67. Therefore, by monitoring the measurement value of the beam current of each tuning cup 47, it is possible to detect that the wafer W has entered the beam non-irradiation range 67.

Additionally, the step (b) is preferably executed before the wafer W arrives at the reversing end of the reciprocation range 69 as shown in the drawing. In the step (b), the wafer W moving within the one beam non-irradiation range 67 is decelerated (v_{y}→0) by the reciprocating mechanism 54 with respect to the reversing end of the reciprocation range 69 that is also the end of the one beam non-irradiation range 67. In the shown example, the wafer W is decelerated over the entire time in the “BEAM NON-IRRADIATION RANGE”, but the wafer W may be decelerated over a part of time in the “BEAM NON-IRRADIATION RANGE”.

In the step (c-1) at the “REVERSING END” in the third column of FIG. 18, the processor 61 moves the wafer W toward the beam irradiation range 65 by reversing the movement direction of the wafer W with the reciprocating mechanism 54 at the reversing end of the one beam non-irradiation range 67, subsequently to the step (b). As shown in the drawing, in the step (c-1), the wafer W may be stopped for a predetermined stop time at the reversing end of the one beam non-irradiation range 67. During this period, the “wafer speed” is “0”. On the other hand, the change of the wafer W from the first implantation angle to the second implantation angle with the implantation angle adjustment mechanism started in the step (b) continues even while the wafer W is stopped at the reversing end. Additionally, the wafer W moving within the one beam non-irradiation range 67 after the reversal of the movement direction of the wafer W in the step (c-1) is accelerated (0→−v_{y}) toward the beam irradiation range 65 by the reciprocating mechanism 54. In the shown example, the wafer W is accelerated over the entire time in the “BEAM NON-IRRADIATION RANGE”, but the wafer W may be accelerated over a part of time in the “BEAM NON-IRRADIATION RANGE”.

In the step (c-2) in the “BEAM NON-IRRADIATION RANGE” in the fourth column of FIG. 18, the processor 61 completes the change of the wafer W from the first implantation angle to the second implantation angle with the implantation angle adjustment mechanism started in the step (b) while the wafer W is moving within the one beam non-irradiation range 67 before returning from the one beam non-irradiation range 67 to the beam irradiation range 65 with the reciprocating mechanism 54, subsequently to the step (b). In addition, the change of the wafer W from the first implantation angle to the second implantation angle with the implantation angle adjustment mechanism may be completed while the wafer W moves toward the reversing end of the reciprocation range 69 within the one beam non-irradiation range 67 in the “BEAM NON-IRRADIATION RANGE” in the second column or while the wafer W is stopped at the reversing end of the reciprocation range 69 at the “REVERSING END” in the third column.

In the “BEAM IRRADIATION RANGE” in the fifth column of FIG. 18, the processor 61 moves the wafer W adjusted to have the second implantation angle by the step (c-2) toward the other beam non-irradiation range 67 (67D or 67U) within the beam irradiation range 65 with the reciprocating mechanism 54. The second implantation angle corresponds to, for example, the state of FIG. 16B, and the wafer W moving within the beam irradiation range 65 at the twist angle φ₀+90 and the tilt angle θ₀ is irradiated with the ion beam B. A speed −v_{y} (“−” is attached to indicate a speed in a direction opposite to that in the “BEAM IRRADIATION RANGE” in the first column), in the y direction, of the wafer W in this “BEAM IRRADIATION RANGE” may be constant, and may be a speed controlled in accordance with the beam current values measured with the beam current measuring devices 42, 44, or 47 in order to realize a uniform dose distribution as described with respect to the implantation process in FIG. 11. For example, the magnitude of −v_{y} is proportional to the beam current values measured with the side cups 42R and 42L in the implantation process. Alternatively, the magnitude of −v_{y} may be controlled in accordance with the measured beam current values and the position of the wafer W in the y direction in order to realize a desired dose non-uniformity in a wafer processing target surface.

According to the present embodiment, the wafer W at the first implantation angle starts to change to the second implantation angle after the wafer W has moved from the beam irradiation range 65 to the beam non-irradiation range 67 and before the wafer W arrives at the reversing end of the beam non-irradiation range 67 (step (b)), and the wafer W completes to change to the second implantation angle while the wafer W moves or stops within the beam non-irradiation range 67 before returning from the beam non-irradiation range 67 to the beam irradiation range 65 (step (c-2)). In this way, by performing the movement and movement direction reversal of the wafer W within the beam non-irradiation range 67 and the change of the implantation angle in parallel, the stay time of the wafer W in the beam non-irradiation range 67 can be shortened. As a result, since the stay time in the beam irradiation range 65, for which the wafer W is irradiated with the scan beam SB, is relatively long, the efficiency of the ion implantation processing can be improved.

In order to complete the change from the first implantation angle to the second implantation angle while the wafer W stays in the beam non-irradiation range 67, the sum of a time T1 for which the wafer W moves toward the reversing end of the beam non-irradiation range 67 within the beam non-irradiation range 67, a stop time T2 at the reversing end, and a time T3 for which the wafer W moves toward the beam irradiation range 65 within the beam non-irradiation range 67 is set preferably to be equal to or more than the time required for the wafer W to change from the first implantation angle to the second implantation angle with the implantation angle adjustment mechanism. Specifically, it is preferable that T1+T2+T3 is 0.05 seconds or more and 1 second or less, 0.2 seconds or more and 0.8 seconds or less, 0.3 seconds or more and 0.6 seconds or less, or the like. In particular, the stop time T2 at the reversing end is preferably greater than 0 seconds and 0.45 seconds or less.

In a case where the change of the wafer W from the first implantation angle to the second implantation angle with the implantation angle adjustment mechanism can be completed without stopping the wafer W at the reversing end, the stay time T1+T2+T3 of the wafer W in the beam non-irradiation range 67 is minimized (T2=0). On the other hand, in a case where the change of the wafer W from the first implantation angle to the second implantation angle with the implantation angle adjustment mechanism cannot be completed only by a reciprocation time T1+T3 of the wafer W in the beam non-irradiation range 67, the wafer W may be stopped at the reversing end for the time T2 additionally required for the change of the implantation angle. In other words, the stop time T2 of the wafer W at the reversing end can be flexibly set from the viewpoint of completing the change of the implantation angle.

The “BEAM DEFLECTION DEVICE” in the third row and the “BEAM BLOCKING MECHANISM” in the fourth row in FIG. 18 are controlled by the processor 61 in order to reliably retract the ion beam B such that the wafer W is not erroneously irradiated with the scan beam SB while the implantation angle of the wafer W within the beam non-irradiation range 67 is changed. “ON” and “OFF” in the “BEAM DEFLECTION DEVICE” indicate operating states of the beam deflection device 24. During “ON”, the beam deflection device 24 deflects the ion beam B in the irradiation-disabled direction, and during “OFF” when the beam deflection device 24 is not operating, the ion beam B travels in the irradiation-enabled direction. “ON” and “OFF” in the “BEAM BLOCKING MECHANISM” indicate operating states of the beam blocking mechanism 28. During “ON”, the beam blocking mechanism 28 is in the blocking state in which the ion beam B is physically blocked, and during “OFF”, the beam blocking mechanism 28 is in the non-blocking state in which the ion beam B is allowed to pass through.

In the step (d), the processor 61 switches the beam deflection device 24 to the irradiation-disabled state “ON” before the change of the wafer W from the first implantation angle to the second implantation angle with the implantation angle adjustment mechanism is started while the wafer W is moving within the beam non-irradiation range 67 with the reciprocating mechanism 54 in the step (b). In the step (f), the processor 61 switches the beam blocking mechanism 28 to the blocking state “ON” after the step (d). The step (f) is preferably executed before the change of the wafer W from the first implantation angle to the second implantation angle with the implantation angle adjustment mechanism is started in the step (b). Since the ion beam B deflected by the beam deflection device 24 travels in the irradiation-disabled direction, and furthermore the beam blocking mechanism 28 physically blocks the ion beam B in preparation for a case that the beam deflection device 24 does not normally operate, the wafer W can be reliably prevented from be erroneously irradiated with the scan beam SB while the implantation angle of the wafer W within the beam non-irradiation range 67 is being changed.

In the step (e), the processor 61 switches the beam deflection device 24 to the irradiation-enabled state “OFF” after the change of the wafer W from the first implantation angle to the second implantation angle with the implantation angle adjustment mechanism in the step (c-2) is completed while the wafer W is moving within the beam non-irradiation range 67 with the reciprocating mechanism 54 in the step (c-1). In the step (g), the processor 61 switches the beam blocking mechanism 28 to the non-blocking state “OFF” before the step (e). The step (g) is preferably executed after the change of the wafer W from the first implantation angle to the second implantation angle with the implantation angle adjustment mechanism is completed in the step (c-2).

Subsequently, modification examples of the basic operation in the implantation process of the ion implanter 10 will be described.

In a first modification example, in addition to the beam blocking mechanism 28, the first beam current measuring device 46 and/or the second beam current measuring device 42 is used. In a case where a beam current equal to or greater than a first predetermined value is not measured with the first beam current measuring device 46 (such as the beam stopper 46 or the like configured as a beam current measuring device) that measures a beam current of an ion beam directed in the irradiation-enabled direction, the processor 61 may make a determination of being in the irradiation-disabled state to switch the beam blocking mechanism 28 to the blocking state. That is, in a case where the beam current measured with the first beam current measuring device 46 is smaller than the first predetermined value, there is a risk that the intensity of the ion beam to be used for the ion implantation processing in the implantation processing chamber 16 is insufficient. Therefore, the beam blocking mechanism 28 is switched to the blocking state, and then the ion implantation processing is interrupted or stopped. In addition to or instead of the first beam current measuring device 46, in a case where the beam current of the first predetermined value or more or the beam current of a predetermined value equivalent to the first predetermined value or more is not measured with the second beam current measuring device 42 (side cups 42 or the like) or the tuning cups 47, the processor 61 may make a determination of being in the irradiation-disabled state to switch the beam blocking mechanism 28 to the blocking state.

In a case where a beam current equal to or greater than a second predetermined value is measured with the second beam current measuring device 42 (side cups 42 or the like) that measures the beam current of the ion beam directed in the irradiation-disabled direction, the processor 61 may make a determination of being in the irradiation-disabled state to switch the beam blocking mechanism 28 to the blocking state. That is, in a case where the beam current measured with the second beam current measuring device 42 is equal to or greater than the second predetermined value, there is a risk that the intensity of the ion beam that is not used for the ion implantation processing in the implantation processing chamber 16 is excessive. Therefore, the beam blocking mechanism 28 is switched to the blocking state, and then the ion implantation processing is interrupted or stopped. In addition, the second predetermined value is preferably set such that the beam current density converted from the second predetermined value is greater than the beam current density converted from the first predetermined value.

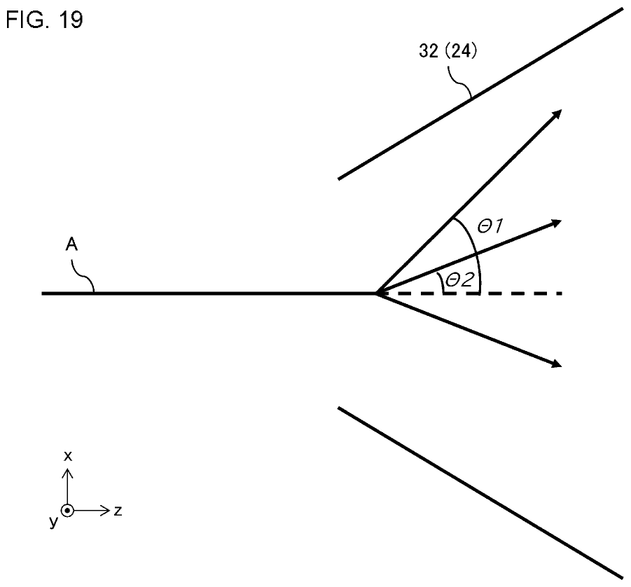

In a second modification example, the beam scanning device 32 is also used as the beam deflection device 24. For example, the beam scanning device 32 realizes the function of the beam deflection device 24 instead of or in addition to the beam park device 24 that has functioned as the beam deflection device 24 in FIGS. 1 and 2. In this case, the beam deflection device 24 and the beam scanning device 32 are the same device. FIG. 19 schematically shows an example in which a beam scanning function as the beam scanning device 32 and a beam deflection function as the beam deflection device 24 are realized by one beam scanning device 32.

In a case where an original beam scanning function is realized, the beam scanning device 32 performs the reciprocating scanning in the predetermined scanning angle range (irradiation range 66 in FIG. 10) in the x direction with the ion beam with which the wafer W is irradiated. Here, the scanning angle range is an angle range including the irradiation-enabled direction (the direction of the beamline A that can reach a wafer), and a shown θ2 is a maximum scanning angle formed between an outermost angle of the scanning angle range and a reference trajectory direction (the direction of the beamline A in a non-scanning state in which a voltage to be applied between a pair of scanning electrodes of the beam scanning device 32 is substantially zero). In other words, the scanning angle range of the beam scanning device 32 is a range of ±θ2 with respect to the reference trajectory direction.

On the other hand, in a case where the beam scanning device 32 functions as the beam deflection device 24, the ion beam is deflected in the irradiation-disabled direction outside the scanning angle range. Here, a deflection angle θ1 of the ion beam is an angle formed between the irradiation-disabled direction and the reference trajectory direction, and is greater than the maximum scanning angle θ2 (θ1>θ2). Since the wafer W is not disposed on the path of the ion beam deflected by the deflection angle θ1, the deflection angle θ1 is set to the irradiation-disabled direction in which the wafer W cannot be irradiated with the ion beam. In addition, the beam scanning device 32 functioning as the beam deflection device 24 may deflect the ion beam at a deflection angle of −θ1. Additionally, a beam dump or the like may be provided on the path of the ion beam deflected at the deflection angle θ1 (or −θ1) such that the ion beam collides with the beam dump or the like and is shielded.

In the “BEAM IRRADIATION RANGE” in the basic operation of the implantation process in FIG. 18, the beam scanning device 32 realizes the original beam scanning function, and performs the reciprocating scanning in a scanning angle range (−θ2 to +θ2) with the ion beam with which the wafer W is irradiated. Additionally, in the “BEAM NON-IRRADIATION RANGE” and the “REVERSING END” in the basic operation of the implantation process in FIG. 18, the beam scanning device 32 functions as the beam deflection device 24, and deflects the ion beam in the irradiation-disabled direction (θ1 or −θ1) outside the scanning angle range.

The present invention has been described above on the basis of the embodiment. The embodiment is an example, and it will be understood by those skilled in the art that various modification examples are possible for the combinations of the respective components and the respective processes and that such modification examples are also within the scope of the present invention.

In addition, the functional configurations of the respective devices described in the embodiment can be realized by hardware resources or software resources or by the cooperation between the hardware resources and the software resources. Processors, ROMs, RAMs, and other LSIs can be used as the hardware resources. Programs such as operating systems and applications can be used as the software resources.

It should be understood that the invention is not limited to the above-described embodiment, but may be modified into various forms on the basis of the spirit of the invention. Additionally, the modifications are included in the scope of the invention.

What is claimed is:

1. An ion implanter comprising:
a support mechanism that supports a workpiece to be irradiated with an ion beam;
an implantation angle adjustment mechanism capable of adjusting an implantation angle of the workpiece supported with the support mechanism with respect to the ion beam;
a drive mechanism that reciprocates the support mechanism in a direction intersecting with the ion beam, wherein a reciprocation range of the drive mechanism includes a beam irradiation range in which at least a part of the workpiece is irradiated with the ion beam, and a beam non-irradiation range which is adjacent to at least one end of the beam irradiation range and in which the workpiece is not irradiated with the ion beam;
a processor that controls the implantation angle adjustment mechanism and the drive mechanism; and
a memory in which a program is stored;
wherein on the basis of the program, the processor executes
(a) moving the workpiece, which has been adjusted so as to have a first implantation angle by the implantation angle adjustment mechanism, from the beam irradiation range toward the beam non-irradiation range with the drive mechanism;
(b) starting a change of the workpiece from the first implantation angle to a second implantation angle different from the first implantation angle with the implantation angle adjustment mechanism while the workpiece is moved within the beam non-irradiation range after the workpiece having the first implantation angle is moved from the beam irradiation range to the beam non-irradiation range with the drive mechanism, subsequently to the step (a);
(c-1) reversing a movement direction of the workpiece at an end of the beam non-irradiation range with the drive mechanism and moving the workpiece toward the beam irradiation range, subsequently to the step (b); and
(c-2) completing the change of the workpiece from the first implantation angle to the second implantation angle with the implantation angle adjustment mechanism while the workpiece is moved within the beam non-irradiation range with the drive mechanism before the workpiece is returned from the beam non-irradiation range to the beam irradiation range with the drive mechanism, subsequently to the step (b).

2. The ion implanter according to claim 1,
wherein the beam non-irradiation range includes a first beam non-irradiation range adjacent to one end of the beam irradiation range and a second beam non-irradiation range adjacent to the other end of the beam irradiation range.

3. The ion implanter according to claim 1, further comprising:
a beam current measuring device for dose control that measures in a case where the workpiece is irradiated with a part of the ion beam, as a beam current, another part of the ion beam with which the workpiece is not irradiated;
wherein in the step (a), the drive mechanism moves the workpiece within the beam irradiation range at a speed controlled depending on the beam current measured with the beam current measuring device.

4. The ion implanter according to claim 1,
wherein in the step (b), the workpiece that is moved within the beam non-irradiation range is decelerated with the drive mechanism with respect to the end of the beam non-irradiation range.

5. The ion implanter according to claim 1,
wherein in the step (c-1), the workpiece that is moved within the beam non-irradiation range is accelerated with the drive mechanism toward the beam irradiation range.

6. The ion implanter according to claim 1,
wherein in the step (c-1), the workpiece is stopped for a predetermined stop time at the end of the beam non-irradiation range.

7. The ion implanter according to claim 6,
wherein a sum of a time taken for the workpiece to move within the beam non-irradiation range toward the end of the beam non-irradiation range in the step (b), the stop time, and a time taken for the workpiece to move within the beam non-irradiation range toward the beam irradiation range in the step (c-1) is equal to or longer than a time required for the change of the workpiece from the first implantation angle to the second implantation angle with the implantation angle adjustment mechanism.

8. The ion implanter according to claim 7,
wherein the sum of the time taken for the workpiece to move within the beam non-irradiation range toward the end of the beam non-irradiation range in the step (b), the stop time, and the time taken for the workpiece to move within the beam non-irradiation range toward the beam irradiation range in the step (c-1) is 0.05 seconds or more and 1 second or less.

9. The ion implanter according to claim 8,
wherein the stop time is longer than 0 seconds and equal to or shorter than 0.45 seconds.

10. The ion implanter according to claim 1,
wherein the implantation angle adjustment mechanism includes a twist angle adjustment mechanism that adjusts a twist angle of the workpiece having a normal line, which is perpendicular to a processed surface at a center of the workpiece surface of the processed supported with the support mechanism, as a rotation axis, and
the twist angle adjustment mechanism adjusts a twist angle in the first implantation angle to a first twist angle and adjusts a twist angle in the second implantation angle to a second twist angle different from the first twist angle.

11. The ion implanter according to claim 10,
wherein a difference between the first twist angle and the second twist angle is larger than 0 degrees and equal to or smaller than 180 degrees.

12. The ion implanter according to claim 10,
wherein in a case where the processor executes the steps (a) to (c-2) N times (N is a natural number equal to or larger than 2), a difference between the first twist angle and the second twist angle is equal for all N times.

13. The ion implanter according to claim 12,
wherein the N is an even number which is 2 or more and 32 or less.

14. The ion implanter according to claim 13,
wherein the difference between the first twist angle and the second twist angle is an angle obtained by dividing 360 degrees by the N.

15. The ion implanter according to claim 1, further comprising:
an electrostatic holding mechanism that holds the workpiece supported with the support mechanism by electrostatic attraction.

16. The ion implanter according to claim 1, further comprising:
a beam deflection device that deflects the ion beam with at least one of an electric field and a magnetic field, and that is switchable between an irradiation-enabled state in which the ion beam is directed in an irradiation-enabled direction in which the workpiece is capable of being irradiated with the ion beam, and an irradiation-disabled state in which the ion beam is directed in an irradiation-disabled direction in which the workpiece is incapable of being irradiated with the ion beam, wherein on the basis of the program, the processor executes
(d) switching the beam deflection device to the irradiation disabled state before a change of the workpiece from the first implantation angle to the second implantation angle with the implantation angle adjustment mechanism is started while the workpiece is moved within the beam non-irradiation range with the drive mechanism in the step (b); and
(e) switching the beam deflection device to the irradiation enabled state after the change of the workpiece from the first implantation angle to the second implantation angle with the implantation angle adjustment mechanism in the step (c-2) is completed while the workpiece is moved within the beam non-irradiation range with the drive mechanism in the step (c-1).

17. The ion implanter according to claim 16,
wherein the beam deflection device includes a pair of electrodes facing each other with the ion beam interposed therebetween and is switchable between the irradiation enabled state and the irradiation disabled state depending on an electric field change caused by a change in a voltage to be applied to the pair of electrodes.

18. The ion implanter according to claim 16,
wherein the beam deflection device includes a pair of magnetic poles facing each other with the ion beam interposed therebetween, a yoke that magnetically connects the pair of magnetic poles to each other, and a coil that is wound around at least one of the magnetic poles and the yoke, and is switchable between the irradiation enabled state and the irradiation disabled state depending on a magnetic field change caused by a change in a current to be applied to the coil.

19. The ion implanter according to claim 16,
wherein a slit is provided between the beam deflection device and the support mechanism, the slit allows at least part of the ion beam directed in the irradiation-enabled direction to pass therethrough, and
the ion beam directed in the irradiation disabled direction collides with an outside of the slit and is blocked.

20. The ion implanter according to claim 16,
wherein a deflection angle formed between the irradiation-enabled direction and the irradiation-disabled direction is from 2 degrees to 60 degrees.

21. The ion implanter according to claim 20,
wherein the deflection angle formed between the irradiation-enabled direction and the irradiation-disabled direction is from 3 degrees to 45 degrees.

22. The ion implanter according to claim 21,
wherein the deflection angle formed between the irradiation-enabled direction and the irradiation-disabled direction is from 5 degrees to 30 degrees.

23. The ion implanter according to claim 16, further comprising:
a beam scanning device that scans a predetermined scanning angle range with the ion beam with which the workpiece is irradiated by at least one of the electric field and the magnetic field.

24. The ion implanter according to claim 23,
wherein the beam deflection device and the beam scanning device are the same device,
the scanning angle range includes the irradiation-enabled direction; and
a maximum scanning angle that is formed between an outermost angle of the scanning angle range and a reference trajectory direction in a state in which scanning is not performed with the ion beam is smaller than a deflection angle that is formed between the irradiation disabled direction and the reference trajectory direction.

25. The ion implanter according to claim 16, further comprising:
a beam blocking mechanism that is switchable between a blocking state in which the ion beam is physically blocked and a non-blocking state in which the ion beam is passed.

26. The ion implanter according to claim 25,
wherein the processor switches the beam blocking mechanism to the blocking state after the step (d) and switches the beam blocking mechanism to the non-blocking state before the step (e).

27. The ion implanter according to claim 25, further comprising:
a first beam current measuring device that measures a beam current of the ion beam directed in the irradiation enabled direction,
wherein the processor determines that the beam deflection device is in the irradiation-disabled state and switches the beam blocking mechanism to the blocking state in a case where a beam current equal to or larger than a first predetermined value is not measured with the first beam current measuring device.

28. The ion implanter according to claim 25, further comprising:
a second beam current measuring device that measures a beam current of the ion beam directed in the irradiation-disabled direction,
wherein the processor determines that the beam deflection device is in the irradiation-disabled state and switches the beam blocking mechanism to the blocking state in a case where a beam current equal to or larger than a second predetermined value is measured with the second beam current measuring device.

29. An ion implantation method comprising:
(a) moving a workpiece adjusted to have a first implantation angle with respect to an ion beam from a beam irradiation range in which at least a part of the workpiece is irradiated with the ion beam toward a beam non-irradiation range which is adjacent to at least one end of the beam irradiation range and in which the workpiece is not irradiated with the ion beam;
(b) starting a change of the workpiece from the first implantation angle to a second implantation angle different from the first implantation angle while the workpiece is moved within the beam non-irradiation range after the workpiece having the first implantation angle is moved from the beam irradiation range to the beam non-irradiation range, subsequently to the step (a);
(c-1) reversing a movement direction of the workpiece at an end of the beam non-irradiation range and moving the workpiece toward the beam irradiation range, subsequently to the step (b); and
(c-2) completing the change of the workpiece from the first implantation angle to the second implantation angle while the workpiece is moved within the beam non-irradiation range before the workpiece is returned from the beam non-irradiation range to the beam irradiation range, subsequently to the step (b).

30. The ion implantation method according to claim 29,
wherein the beam non-irradiation range includes a first beam non-irradiation range adjacent to one end of the beam irradiation range and a second beam non-irradiation range adjacent to the other end of the beam irradiation range.

31. The ion implantation method according to claim 29,
wherein in the step (a), in a case where the workpiece is irradiated with a part of the ion beam, another part of the ion beam with which the workpiece is not irradiated is measured as a beam current and the workpiece is moved at a speed controlled depending on the measured beam current within the beam irradiation range.

32. The ion implantation method according to claim 29,
wherein in the step (b), the workpiece that is moved within the beam non-irradiation range is decelerated with respect to the end of the beam non-irradiation range.

33. The ion implantation method according to claim 29,
wherein in the step (c-1), the workpiece that is moved within the beam non-irradiation range is accelerated toward the beam irradiation range.

34. The ion implantation method according to claim 29,
wherein in the step (c-1), the workpiece is stopped for a predetermined stop time at the end of the beam non-irradiation range.

35. The ion implantation method according to claim 34,
wherein a sum of a time taken for the workpiece to move within the beam non-irradiation range toward the end of the beam non-irradiation range in the step (b), the stop time, and a time taken for the workpiece to move within the beam non-irradiation range toward the beam irradiation range in the step (c-1) is equal or longer than a time required for the change of the workpiece from the first implantation angle to the second implantation angle.

36. The ion implantation method according to claim 29, further comprising:
(d) changing at least one of an electric field and a magnetic field to deflect the ion beam in an irradiation-disabled direction in which the workpiece is incapable of being irradiated with the ion beam before the change of the workpiece from the first implantation angle to the second implantation angle is started while the workpiece is moved within the beam non-irradiation range in the step (b); and
(e) changing at least one of the electric field and the magnetic field to return the ion beam in an irradiation-enabled direction in which the workpiece is capable of being irradiated with the ion beam after the change of the workpiece from the first implantation angle to the second implantation angle in the step (c-2) is completed while the workpiece is moved within the beam non-irradiation range in the step (c-1).
